(19) United States
(12) Patent Application Publication
(10) Pub. No.: US 2005/0266691 A1
(43) Pub. Date: Dec. 1, 2005

(54) Carbon-doped-Si oxide etch using H2 additive in fluorocarbon etch chemistry

(75) Inventors: Binxi Gu, Cupertino, CA (US); Gerardo A. Delgadino, Santa Clara, CA (US); Yan Ye, Saratoga, CA (US); Mike Ming Yu Chen, Santa Clara, CA (US)

Correspondence Address: AAGAARD & BALZAN, LLP, 674 COUNTY SQUARE DRIVE, SUITE 105, VENTURA, CA, 93003, US

(73) Assignee: Applied Materials Inc.

(21) Appl. No.: 11/126,053

(22) Filed: May 9, 2005

Related U.S. Application Data
(60) Provisional application No. 60/570,524, filed on May 11, 2004.

(51) Int. Cl. H01L 21/302; B44C 1/22

(52) U.S. Cl. 438/706; 438/710; 438/718; 438/723; 216/67

(57) ABSTRACT

Certain embodiments include an etching method including providing an etch material, applying a gas mixture including hydrogen, forming a plasma, and etching the etch material. The etch material can include a low-k dielectric material. The gas mixture can include a hydrogen gas, a hydrogen-free fluorocarbon, and a nitrogen gas, and further include one or more of a hydrofluorocarbon gas, an inert gas, and/or a carbon monoxide gas. The hydrogen gas can be a diatomic hydrogen, a hydrocarbon, a silane and/or a fluorine-free hydrogen gas, including H₂, CH₄, C₂H₄, NH₃, and/or H₂O gases. The hydrogen-free fluorocarbon gas can be a CₓF_{y} gas (where x≧1 and Y≧1) and the hydrofluorocarbon gas can be a CₓH_{y}F_{z} gas (where x≧1, y≧1 and z≧1). The gas mixture can be free of oxygen. Embodiments can include reduced pressures, reduced hydrogen flow rates and one or more plasma frequencies.

This application claims the benefit of U.S. Provisional Application No. 60/570,524, filed on May 11, 2004.

### BACKGROUND

One common step in the fabrication of semi-conductor or thin-film devices is etching. Etching can be a wet etch, where a liquid acid is typically used, or a dry etch, which is a more common method involving the application of a plasma to etch the device.

During a dry etch it is highly desirable to have the etch form features, such as vias and trenches, that are well defined with sidewalls as vertical as possible and bottoms as flat as possible. Vertical sidewalls are beneficial as they allow for the creation of structures which are deeper, e.g. with higher aspect ratios, and more uniform. Flat bottoms allow for better connections to be formed between device components. Well defined structures reduce the potential for defects, such as shorting or incomplete connections, and as a result, can increase the overall production yield. Further, the density of devices and components can be increased as the separation needed between features or elements can be reduced.

It is also highly desirable to reduce the time necessary to complete an etching step, as this allows the production rate to be increased. One way that has been attempted to decrease the etch time has been to increase the etch rate. However, as etch rates have risen, etch quality has tended to drop, which in turn has offset any increase in production with lower device yields. Quality problems have included reduced selectivity, striations, micro-loading, tapered profiles, inadequate etch depth, and early etch termination.

Therefore, a need exists for etching methods that provide increased etch quality and higher etch rates while maintaining or raising the resulting etch quality.

### SUMMARY

In some embodiments, the present invention is a plasma etching method which includes which includes providing an etch material, applying a gas mixture comprising hydrogen, forming a plasma, and etching the etch material.

The etch material can include a low-k dielectric material, an ARC layer and/or a barrier layer, and these layers can be etched in one or more steps, depending on the particular embodiment. Embodiments have the dielectric constant of the low-k dielectric material with values less than 4.0. In at least one embodiment, the dielectric material is a carbon-doped silicon oxide.

In some embodiments the gas mixture includes a hydrogen gas, a hydrogen-free fluorocarbon, and a nitrogen gas. Embodiments have the gas mixture further including one or more of a hydrofluorocarbon gas, an inert gas, and/or a carbon monoxide gas. The hydrogen gas can include a diatomic hydrogen, a hydrocarbon, a silane and/or a fluorine-free hydrogen gas, including H₂, CH₄, C₂H₄, NH₃, and/or H₂O gases. In certain embodiments, the hydrogen-free fluorocarbon gas can include a CₓF_{y} gas (where x≧1 and Y≧1), the nitrogen gas can be a N₂ gas, the hydrofluorocarbon gas can include a CₓH_{y}F_{z} gas (where x≧1, y≧1 and z≧1), the inert gas can include He, Ne, Kr, Xe, and/or Ar. In at least one embodiment, the gas mixture is free of oxygen.

In some embodiments, the gas mixture is applied at a pressure between about 5 mTorr and about 400 mTorr and in others at a pressure between about 5 mTorr and about 30 mTorr. The plasma can be formed at one or more frequencies, including 2 MHz 13.56 MHz and 162 MHz, depending on the embodiment. In some embodiments, the plasma can be formed with a source power between about 0 Watts and about 2000 Watts and a bias power between about 300 Watts and about 3000 Watts.

Embodiments have the flow rate of hydrogen gas between about 10 sccm and about 250 sccm, with certain embodiments having the flow rate reduced to between about 10 sccm and about 75 sccm, the flow rate of hydrogen-free fluorocarbon gas between about 20 sccm and about 200 sccm, the flow rate of hydrofluorocarbon gas between about 20 sccm and about 200 sccm, and flow rate of a hydrogen-free fluorocarbon and hydrofluorocarbon gas between about 10 sccm and about 200 sccm.

Certain embodiments have a gas mixture which includes a hydrogen free-fluorocarbon-containing etchant gas, a hydrogen-containing non-etchant gas, a nitrogen-containing gas, and an inert gas.

### BRIEF SUMMARY OF THE DRAWINGS

FIGS. 1A-F are side views of an etching process in accordance with at least one embodiment of the present invention.

FIGS. 2A-J are flow charts of etching methods in accordance with embodiments of the present invention.

FIGS. 3A-C are side views of an etching process in accordance with at least one embodiment of the present invention.

FIGS. 4A-E are side views of an etching process in accordance with at least one embodiment of the present invention.

FIG. 5 is a side view of a structure in accordance with at least one embodiment of the present invention.

FIG. 6 is a side view of structures in accordance with at least one embodiment of the present invention.

FIG. 7 is a side view of a structure in accordance with at least one embodiment of the present invention.

FIG. 8 is a side view of a structure in accordance with at least one embodiment of the present invention.

FIG. 9 is a side view of a structure in accordance with at least one embodiment of the present invention.

FIG. 10 is a side view of a structure in accordance with at least one embodiment of the present invention.

FIG. 11 is a side views of a structure in accordance with at least one embodiment of the present invention.

FIG. 12 is a side view of a structure in accordance with at least one embodiment of the present invention.

FIG. 13 is a side view of a structure in accordance with at least one embodiment of the present invention.

FIG. 14 is a side view of a structure in accordance with at least one embodiment of the present invention.

FIG. 15 is a side view of a structure in accordance with at least one embodiment of the present invention.

FIG. 16 is a flow chart of an etching method in accordance with embodiments of the present invention.

FIG. 17 is a chamber in accordance with at least one embodiment of the present invention.

### DESCRIPTION

This application claims the benefit of U.S. Provisional Application No. 60/570,524, filed on May 11, 2004. The U.S. Provisional Application No. 60/570,524, filed on May 11, 2004, entitled: CARBON-DOPED-Si OXIDE ETCH USING H2 ADDITIVE IN FLUOROCARBON ETCH CHEMISTRY, by Gu et al., is hereby incorporated herein by reference in its entirety.

In at least one embodiment, the present invention includes a method of etching features into one or more material layers of a structure, while achieving certain desired etch properties and results. In certain embodiments, the Applicant's invention employs a hydrogen gas during the etch. Some of the aspects of the use of hydrogen can include providing certain desired etch profiles, higher selectivities and/or increased etch rates, while reducing or eliminating various adverse etching effects.

In embodiments of the present invention, the use of hydrogen provides the ability to improve, or tune, the etch profiles and feature shapes. For example, hydrogen gas can be used in the gas mixture during the etch to reduce or eliminate the taper of the profile while maintaining a certain selectivity to a bottom barrier in the etched structure, such that a flatter bottom surface can be obtained. Hydrogen also allows for deeper etching while retaining more, or at least about the same amount of, photoresist or PR material. Further, by reducing, or eliminating, the amount and severity of problems such as microtrenching, micro-loading, striations, and/or etch stop by the addition of hydrogen, the resulting etch can be improved.

The use of hydrogen in embodiments of the current invention can reduce or in some cases eliminate micro-trenching. Adverse effects from micro-trenching can include the creation of voids, increased electrical resistance, increase capacitance and leakage. During some etching, voids can be created at the areas of the micro-trenching as a material is deposited in the feature about the micro-trenches. Such voids will cause the deposited material to have a reduced cross-sectional area relative to the area available with a completely filled feature. With conductive materials, such as copper, deposited into the etched feature the reduction in cross-sectional area will cause an increase in the electrical resistance. Increasing the electrical resistance can cause a reduction in performance of the device.

Micro-trenching can also cause an increase in capacitance between layers by causing conductive materials to be positioned closer together. This can occur either by the micro-trenching causing the feature to compensate for voids by etching deeper to maintain a desired cross-sectional area, or with the material filling the micro-trenches, the conductive trench material is closer to other conductive elements. Increased capacitance can decrease performance by decreasing the signal transport speed of the conductive elements.

With micro-trenching, leakage can occur at the sharp corners of the micro trenches, which can also cause a reduction in performance of the device and potentially shorting.

Depending on the embodiment, the use of hydrogen also allows for a reduction or elimination of micro-loading. These effects of hydrogen can include problems encountered with both profile micro-loading and etch rate micro-loading. As a result, the use of hydrogen during the etch can further aid in achieving desired etch profiles.

The reduction of striations by the addition of hydrogen to the etch gas mixture not only provides for an improved etch quality, but it aids in protecting the photoresist from damage. Striations and pinholes tend to form as the PR layer becomes relatively thin due to etching at low PR selectivities. Striations and pinholes, by providing openings through the PR layer, can cause unwanted etching of the underlying structure. Striations may create problems during Cu barrier deposition increasing Cu diffusion into the dielectric lowering breakdown voltage and/or increasing capacitance. Striations may increase the appearance of voids during the metal deposition increasing resistance and reducing the lifetime of the device. Striations may increase the leakage current between interconnects, especially for misaligned structures. Pinholes may increase capacitance, leakage and enhance poisoning of DUV resists. However, with embodiments that use hydrogen during the etch, a sufficient thickness of the PR layer can be maintained such that the PR layer will not become thin enough for striations and pinholes to form. In at least one of the embodiments, smooth hydrofluorocarbon deposition on the mask may strongly reduce striation formation. This potential reduction in damage to the photoresist has even greater significance with the use of the newer photoresist layers which can be relatively weak and thin.

The addition of hydrogen in embodiments further allows an increase of the selectivity of the material to be etched to the material which is to be retained. More specifically, in embodiments, the use of hydrogen provides a greater etch rate of the dielectric, or similar etched material, relative to the etch rate of the photoresist, in comparison to etching without hydrogen addition. This allows more photoresist material to be retained, and/or thinner photoresist to be used, for a given dielectric etch. For photoresists, allowing the use of thinner material is significant as newer photoresists, such as 193 nm photoresist, trend to be thinner to provide for smaller feature sizes.

In some embodiments of the present invention, the use of hydrogen gas allows for an increase in selectivity to the PR layer by the deposition of polymer material over the PR during the etch. The use of hydrogen can affect the deposition of polymer upon the structure. For instance by using hydrogen, depending on the embodiment, the polymer can be deposited more evenly across the entire etched structure, or the polymer can be selectively deposited in greater amounts over the PR than over areas without PR, or the polymer deposited can have stronger bonds to the PR layer than to other non-PR materials. This deposition over the PR can in some embodiments actually increase the effective thickness of the PR layer, such that an effective infinite PR selectivity is obtained.

By controlling the PR selectivity by the use of hydrogen, embodiments of the present invention provide more defined and uniform openings to etched features, avoiding uneven shaped opening at higher PR selectivities and damage due to striations at lower PR selectivities.

The hydrogen gas can be a non-etchant gas. With certain embodiments of the present invention, the hydrogen used is H₂, a diatomic hydrogen, a hydrogen that is not chemically bonded with elements other than hydrogen, or a pure hydrogen.

In embodiments of the present invention, selectivity can also be increased through the use of various additional gases used during the etch. For example, the use of very polymerizing gases allow the selectivity to layers other than the dielectric layer, to be increased. Lean gases, i.e. those that do not generate an excessive amount of polymer, can be used in combination with other gases to provide higher selectivity. For example, lower carbon containing gases, such as tetrafluoromethane or CF₄, in the presence of H₂, allow for an increase in the PR selectivity during the etch of a dielectric material layer. Low selectivity to the PR layer, e.g. a selectivity below about 1, can be a cause of striation in the PR layer. Another layer that high selectivity is desired is a barrier layer, which, if present, is typically set below the dielectric layer to be etched. H₂ presence tends to reduce selectivity to typical barrier layer material, such as SiC, Si₃N₄ and SiCN.

Depending on the embodiment, in addition to hydrogen, the etch gas mixture can have other gases including fluorocarbon, hydrogen-free fluorocarbon and hydrofluorocarbon gases. Depending on the application, these gases can affect the quality of the etched feature. The hydrogen-free fluorocarbon and hydrofluorocarbon gases can be etchant gases. For example, difluoromethane or CH₂F₂, gas can be used in embodiments to increase the etch rate and produce a somewhat tapered profile. Nitrogen, an inert gas and carbon monoxide can also be added to the gas mixture. In some embodiments, the gas mixture is free of any oxygen.

Embodiments of the present invention can be used in any of a variety of different fabrication processes where etching is employed. That is, embodiments of the Applicants' methods can be performed with a variety of different materials, environments, process steps and settings. For instance, the method can be used in both front-end and back-end applications. As detailed herein, some applications of various embodiments of the present invention can include use in a damascene or dual damascene processes. In such processes, embodiments of the invention can be applied during the etch of the inter-layer dielectric (ILD), inter-metal dielectric (IMD), or like material, to increase the etch rate while achieving a desired level of product quality. Specifically, the present invention can be used to form an OSG via, trench or other like features in ILD, IMD or similar such layers, allowing multilevel interconnect structures in semiconductor integrated circuits to be fabricated. In some embodiments, the ILD or IMD is a carbon doped silicon oxide film structure.

In recent years dual damascene processes have been employed to increase the performance of integrated circuits. The standard aluminum and silicon oxide interconnect structures have been replaced by copper and low-k dielectric materials using dual damascene patterning techniques. The use of dual damascene patterning techniques are typically done during the back-end processing, where the interconnections between devices and components are formed.

Until relatively recently, the back-end processing typically involved using a combination of tungsten plugs and aluminum interconnections. Generally, the aluminum was deposited over a certain region and then selectively etched to define the desired interconnections. However, with a desire to further increase performance, more recently materials with higher conductivities, such as copper, have begun to be used for the interconnects. While the use of copper provides many benefits, it does not allow for forming to be by etching as was done with aluminum.

As a result, fabrication processes were developed to allow deposition of copper without need for a copper etching step. In damascene and dual damascene processes, features, such as vias and trenches, are defined in a first material and then a second material is deposited into these features. The etched first material typically is a dielectric and the deposited second material is a metal, such as copper. Additional layers can be added by a CMP planarization process which provides a deposition surface for forming the next layer. As a result, such a process allows copper interconnections to be selectively formed in one or more layers, without the need to etch the copper.

Employing an interconnect material, such as copper, having a lower electrical resistance with an insulating material positioned between the interconnects, can result in increased capacitance being formed between the interconnect structures or layers. This increased capacitance can adversely effect performance of the device by decreasing the signal transport speed of the interconnects.

By reducing the dielectric constant, k, of the material positioned between the interconnects, the capacitance effects can be reduced and the signal transport speed restored or even increased over that obtained with aluminum interconnects. Low-k dielectrics have included carbon doped silicon oxide and other like materials. The high carbon content of these low-k materials tend to cause them to be difficult to etch as the high amount of carbon byproduct or residue produced during etching can interfere with the etch as it progresses. Added to such interference can be adverse effects of residue or scum produced by the use of deep ultraviolet (DUV) photoresists.

As set forth in detail herein, embodiments of the present invention can be applied to the etch of low-k dielectrics including processes wherein DUV photoresists are used. Embodiments of the Applicant's invention provide an increase in the etch rate of low-k dielectrics, without incurring the adverse effects from residue formation.

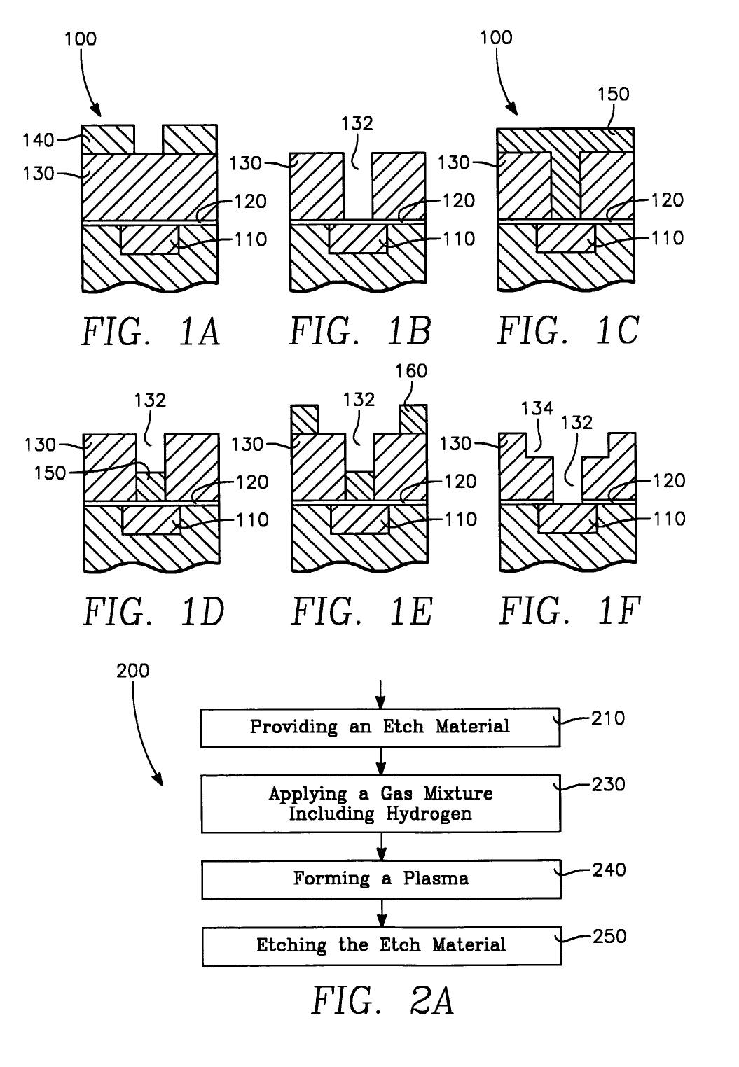

An example of a dual damascene process is set forth in FIGS. 1A-F. As shown, the structure or wafer 100 includes a line 110, a barrier layer 120, an interlayer dielectric or ILD layer 130, and a patterned photoresist 140, as shown in FIG. 1A. FIG. 1B shows that after deposition of the ILD layer 130, a via 132 is patterned in the ILD layer 130. Then, after the via etch and striping of the photoresist 140 in a dielectric etch reactor, the wafer 100 is cleaned and a bottom anti-reflective coating or BARC, resist, or other ARC material 150 is spun on the wafer 100, as shown in FIG. 1C. Then, as shown in FIGS. 1D and E, the wafer 100 is etched back in the plasma reactor and sent back to trench lithography to apply a patterned photoresist layer 160. Finally, as shown in FIG. 1F, a trench 134 is opened, resist 160 and the BARC/Resist/ARC 150 fill is stripped, and the barrier 120 is opened in the dielectric etch reactor.

In some embodiments the present invention is the damascene method as described above. In other embodiments, the method is used during the first step of the damascene process as shown between FIGS. 1A and 1B, wherein the ILD layer 130 is etched. In other embodiments, the method is used later in the process as shown with the etch between FIGS. 1E and F, where the trench 134 is formed by the etch of the ILD layer 130 and where the ARC 150 and barrier 120 are etched.

In addition, there are other interconnect integrations where embodiments of the present invention can be used, including etch back BARC fill, full BARC fill, multilayer resist and Duo-integration.

Specific examples of applications of the present invention include etching an Organo-Silicate Glass, or OSG, low-k dielectric. Where the OSG can be a low-k film used, for example, in 90 nm and below processes. Clearly, this patterning process can be applied to any low-k OSG porous and non porous film. Of course, application of the process of the present invention is not limited to dual damascene structures or to OSG etching.

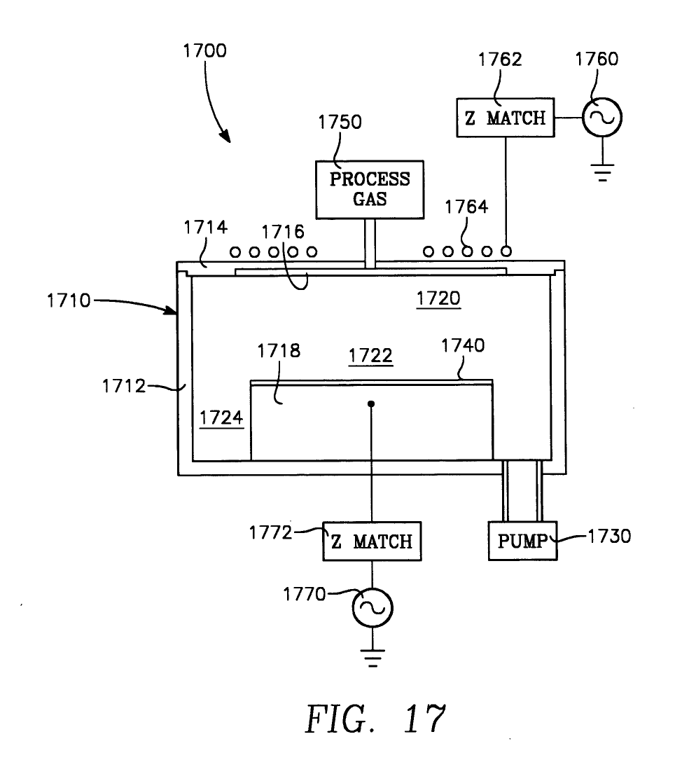

In embodiments, the etch material can be provided into an etching chamber or plasma furnace. Examples of usable etching tools are described herein. One example is a chamber or plasma chamber 1700, as set forth in FIG. 17. The plasma chamber 1700 includes a chamber 1710 having sidewalls 1712, a ceiling 1714, a shower head 1716, and a pedestal 1718. The plasma chamber also includes an interior region 1720, a processing region 1722, a pumping annulus 1724, a vacuum pump 1730, process gas supply 1750, a source power 1760, a match circuit 1762, an antenna 1764, a bias power 1770 and a match circuit 1772.

A wafer 1740 can be positioned on the pedestal 1718 for processing. The shower head 1716 is connected to the gas supply 1750 to provide a gas mixture to the processing region 1722 above the wafer 1740. The source power 1760, match circuit 1762, antenna 1764, bias power 1770 and match circuit 1772 can be used to form a plasma to etch the wafer 1740.

Clearly, any of a variety of different chambers and variations to the chamber 1700 can be used to perform the methods of different embodiments of the present invention.

Etching with a Gas Mixture Including Hydrogen:

Embodiments of the present invention utilize an etching chemistry including hydrogen which can, among other things, enhance the selectivity to a photoresist layer and minimize or eliminate etch profile micro-loading and etch rate micro-loading, while providing a desired etch profile.

In some embodiments, the hydrogen used in the etching gas mixture is H₂ or a diatomic hydrogen.

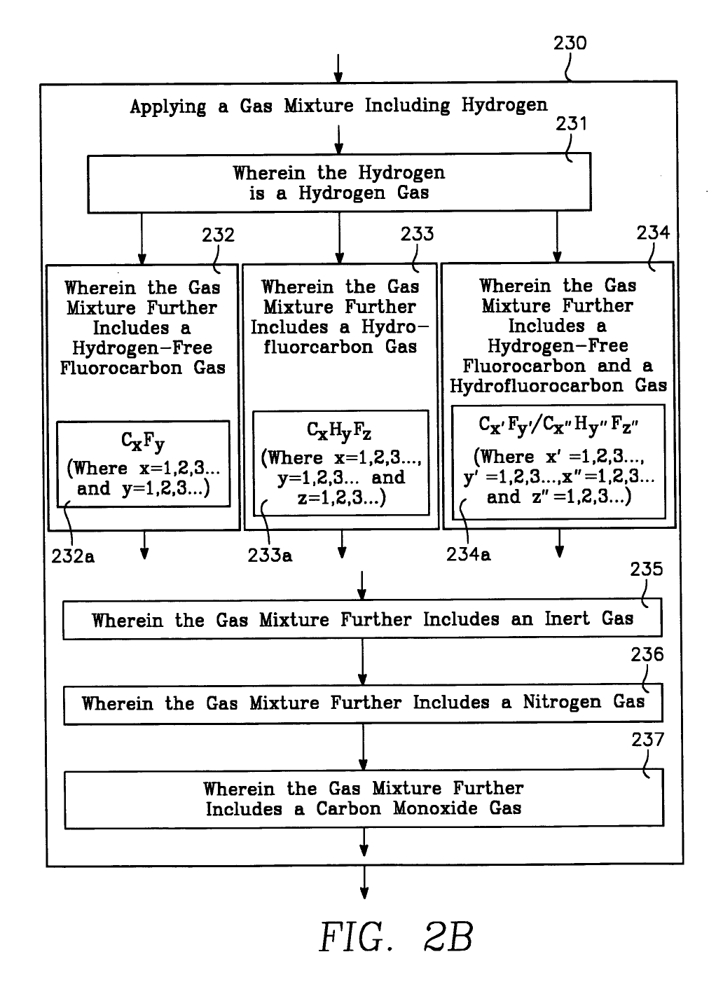

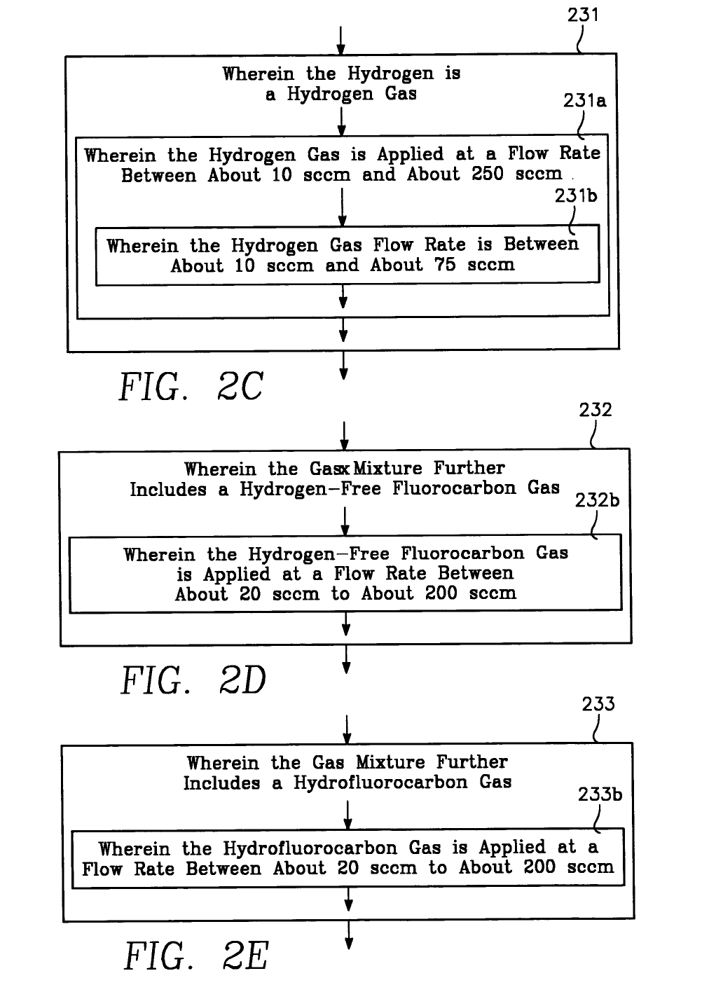

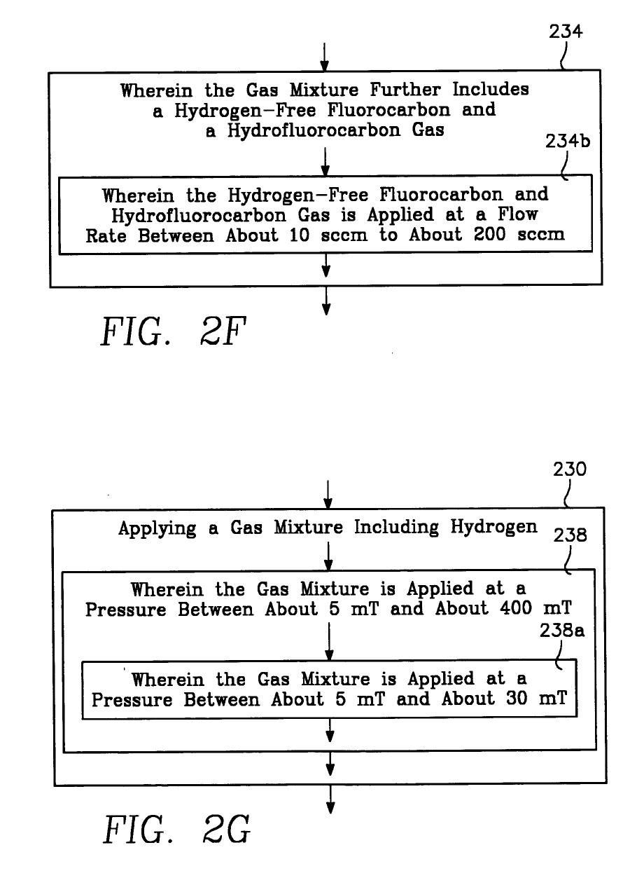

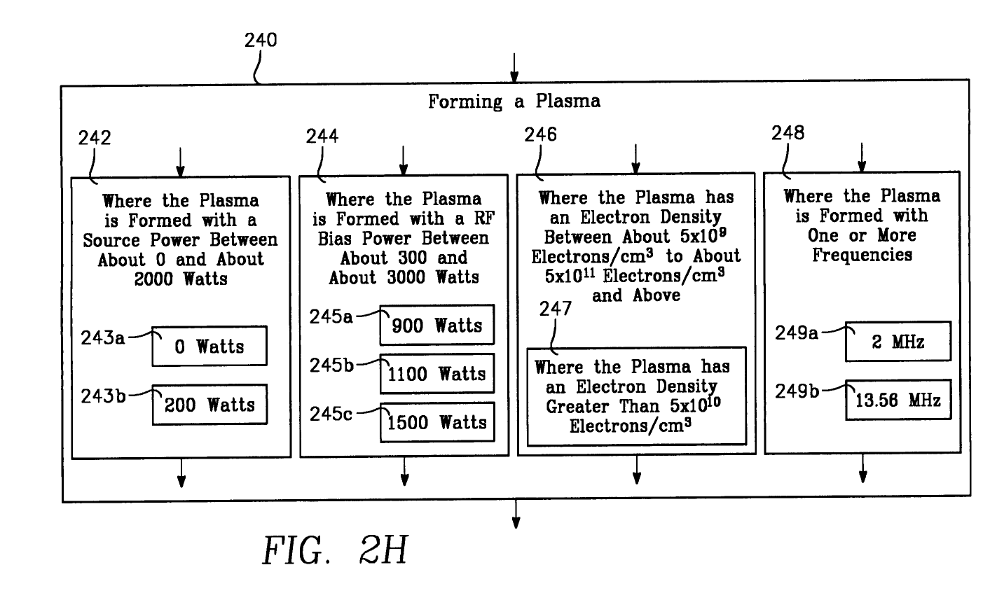

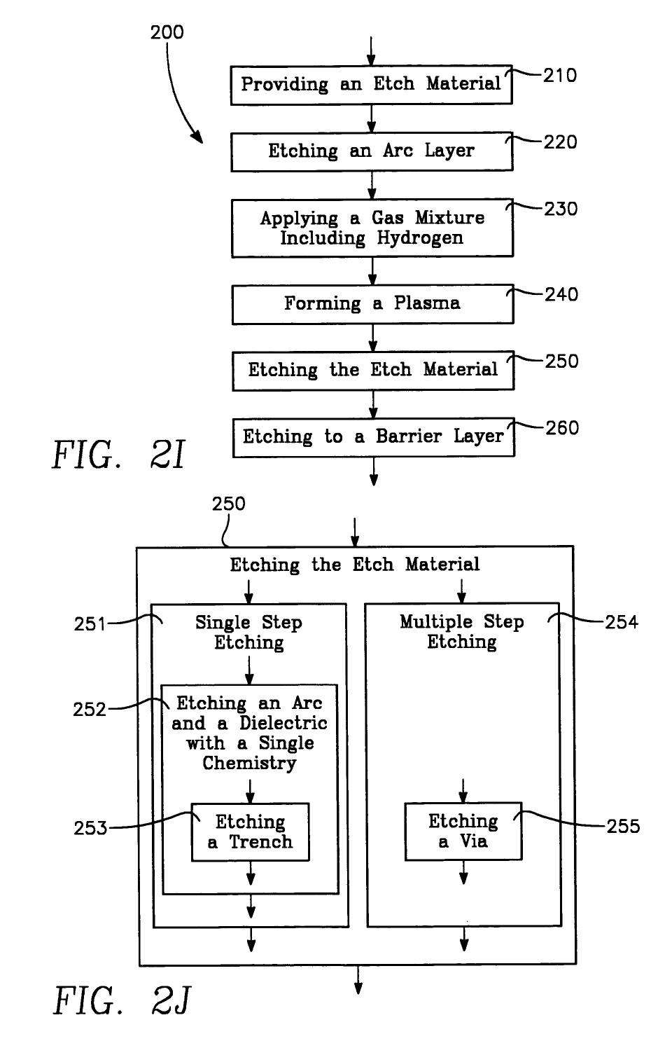

As shown in FIG. 2A, embodiments of the method can include a fabrication method 200 with the steps of providing an etch material 210, applying a gas mixture including hydrogen 230, forming a plasma 240, and etching the etch material 250. As detailed herein, each of these steps can include one or more sub-steps and/or be performed at a variety of different particular values, or range of values, of several different variables. Further, in some embodiments one or more of the steps of the method can be repeated to perform additional etching including for embodiments having two-stage etching, and multiple-stage etching including arc open and over etching, as further described herein.

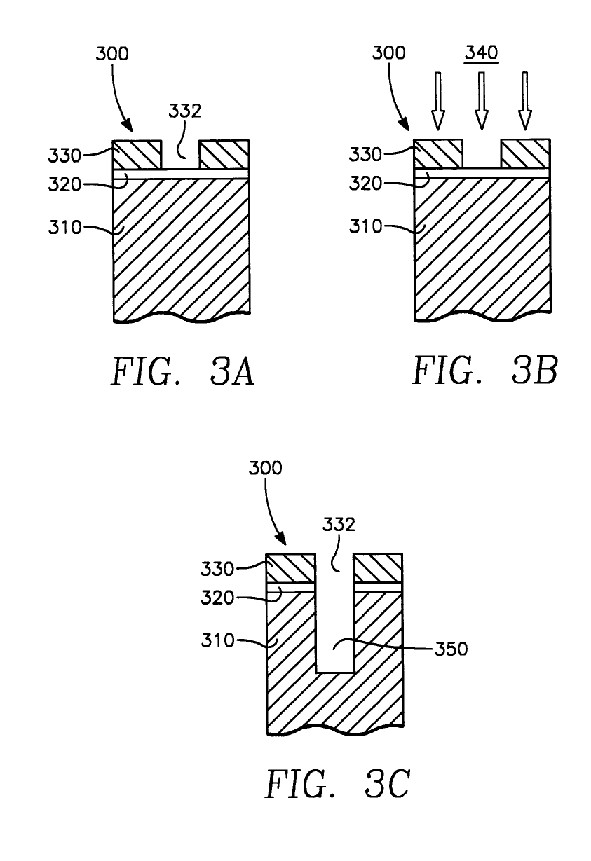

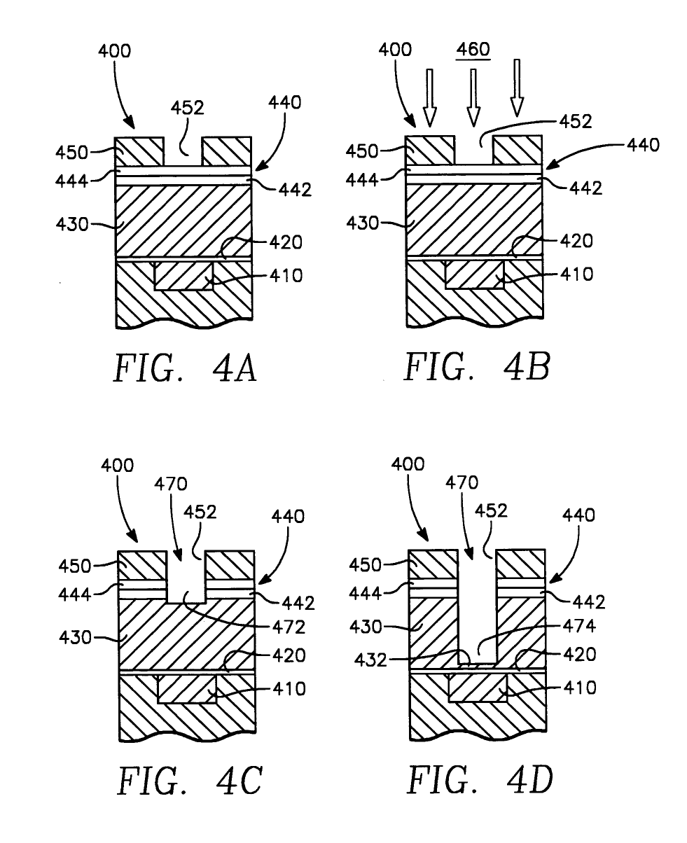

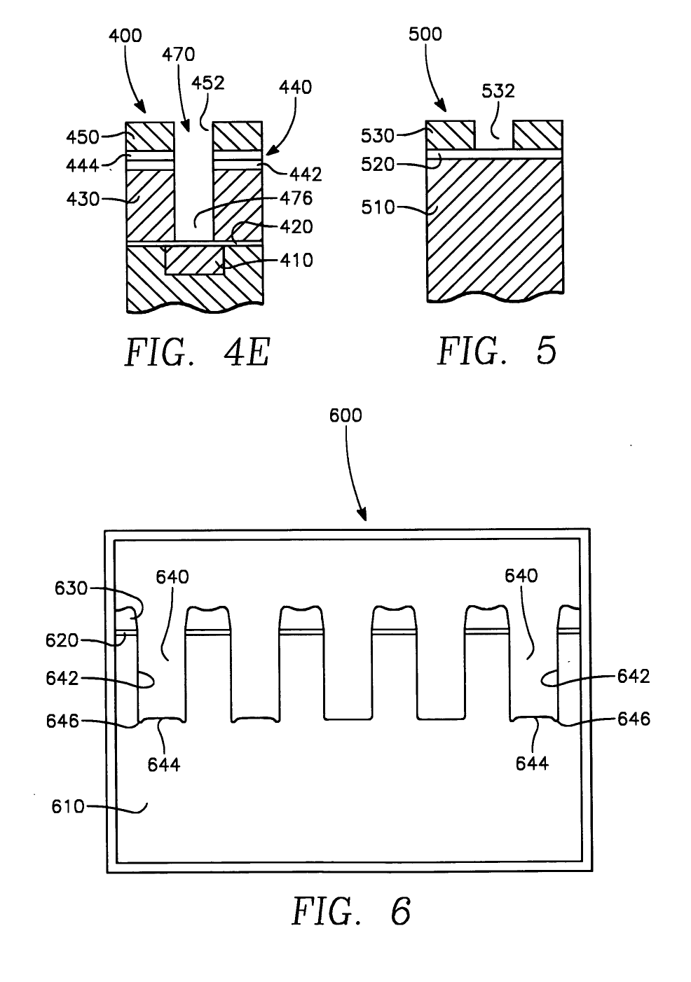

The initial step of the method 200 is providing an etch material 210. This step is shown with two embodiments of a provided etch structure in FIGS. 3A and 4A, other embodiments of a structure are of course usable.

Any of a variety of different materials can be etched by the method 200. In certain embodiments of the present invention, the etch is performed on dielectric materials, including low-k dielectrics. A variety of materials can be etched by the method of the present invention, including materials such as carbon doped silicon oxide, SiO₂, SiO, SiOCH, and the like. The SiO₂ materials can be a silicon dioxide doped with phosphorus or PSG, a P-glass, a phospho-silicate glass or PSG, a boro-phospho-silicate glass or BPSG, a fluorinated silicate glass or FSG., or the like. Because of its doping the BPSG material is usable in front-end etching embodiments of the method. The SiOCH material can include BLACK DIAMOND or BD1 manufactured by Applied Materials, Inc. of San Jose, Calif., U.S.A., having a k between about 3.1 and about 2, AURORA SD manufactured ASM International NV ASMI of Bilthoven, the Netherlands, and CORAL manufactured by Novellus Systems Inc. of San Jose, Calif., USA. The material etched by the method can be spun-on and/or a porous material with a k value of between about 2.5 and 2.2. In other embodiments the dielectric material is deposited by a CVD method.

As noted, etching dielectrics with embodiments of the method provide certain advantages including improved etch results and selectivity. Low-k dielectrics include those having a lower dielectric constant (k) relative to other known dielectric materials, such as SiO. These low-k values can include those in the range of about 2.0 to about 3.7. Some particular examples of such low-k dielectric materials are described herein. These materials can be used in a variety of different applications including Inter-Layer Dielectrics or ILDs and Inter-Metal Dielectrics or IMDs.

FIG. 3A shows one embodiment of a thin film structure 300 which can be etched by the method 200. Namely, the figure shows a cross-section of the structure 300 having a dielectric layer 310, an anti-reflective coating or ARC 320 over the dielectric layer 310, and a photoresist layer 330 on the ARC 320.

The photoresist 330 can, as shown, be patterned to define a gap 332 that extends down to, and exposes a portion of, the anti-reflective coating layer 320. The gap 332 formed by any of a variety of known photoresist patterning techniques including photolithography. The gap 332 allows for selective etching of the anti-reflective coating 320 and the dielectric layer 310, as shown in FIG. 3C. In some embodiments, the thicknesses for a photoresist layer can range between about 1500 Å and about 7000 Å, depending on the specific material and application.

The anti-reflective coating 320 can be any of a variety of anti-reflective materials. One usable ARC material is a spin-on oxide. With the spin-on oxide having a composition generally similar to that of the low-k dielectric, the same etch chemistry can be used to etch both the ARC and the dielectric, providing for a one-step etch process, as further described herein. One such spin-on oxide is DUO, which is available from Honeywell, Inc., Honeywell Electronic Materials of Sunnyvale, Calif., USA. Other usable ARC's include a BARC material and/or a DARC material, as further described herein.

In certain embodiments, the thickness for a DUO layer is from about 1000 Å to about 2000 Å, for a BARC layer from about 400 Å to about 700 Å, and for a DARC layer from about 600 Å to about 800 Å. Methods of removing the DUO after the etch includes ashing, a wet chemistry or the like.

The dielectric layer 330 can be of a variety of materials such as a carbon doped silicon oxide. Other dielectric materials include those which are set forth herein in greater detail. In certain embodiments, the thickness for the dielectric layer can be from about 1500 Å to about 3000 Å for single damascene and from about 3000 Å to about 6000 Å for dual damascene embodiments.

In some embodiments, structures like, or similar to, that of the structure 300 are used when etching trenches or other large opening features. In other embodiments, a structure with layering such as that of structure 300 can used when etching a trench in a structure having a via, such as for dual damascene embodiments.

FIG. 4A shows another embodiment of a thin film structure 400 which can be etched by the method 200. Namely, the figure shows a cross-section of the structure 400 having a line 410, a barrier layer 420 positioned above the line 410, a dielectric layer 430 upon the barrier 420, an anti-reflective coating or ARC 440 over the dielectric layer 430, and a photoresist layer 450 on the ARC 440.

The photoresist 450 defines a gap 452 that extends down to, and exposes a portion of, the ARC layer 440. The gap 452 formed by any of a variety of known photoresist patterning techniques including photolithography. The gap 452 allows for selective etching of the ARC 440 and the dielectric layer 430, as shown in FIGS. 4C-E. For some embodiments, the thicknesses for the photoresist 450 can range between about 1500 Å and about 7000 Å.

Depending on the embodiment, the anti-reflective coating 440 can include one or more layers. As shown in FIG. 4A the ARC layer 440 is two layers which can include a bottom anti-reflective or BARC layer 442 and a dielectric anti-reflective layer, or DARC layer 444. The BARC layer 442 can be any of a variety of materials. The DARC layer 444 can include SiON or SiO₂ materials. For some embodiments, the typical thickness for a BARC layer is about from about 400 Å to about 700 Å, and for a DARC layer about from about 600 Å to about 800 Å. In some embodiments, the ARC 440 includes only one of either the BARC 442 or the DARC 444. In some embodiments, the ARC 440 includes a ARC layer over a cap layer, where the cap layer can be a TEOS layer.

The dielectric layer 430 can be of the variety of materials, including those set forth herein, and in some embodiments is a carbon doped silicon oxide. In certain embodiments, the thickness for the dielectric layer is from about 1500 Å to about 3000 Å for single damascene and from about 3000 Å to about 6000 Å for dual damascene embodiments.

The barrier layer 420 can be a SiCN or SiC material such as BLOK, BLOK II, or BLOK III, which are each available from Applied Materials, Inc. of San Jose, Calif. Other usable barrier layer materials include SiCN and Si₃N₄. In certain embodiments, the thickness for a barrier layer is from about 300 Å to about 600 Å.

The line 410 can be a metal line, such as copper, aluminum, tungsten, platinum or the like.

In particular embodiments, structures like or similar to that of the structure 400 are used when etching via features or structures containing vias.

The etch material can be provided into an etching chamber or plasma furnace to facilitate additional steps of the method. Examples of usable etching tools are described herein, including that set forth in FIG. 17.

Another step of the method 200 is applying a gas mixture including hydrogen 230, as shown in the flow charts of FIGS. 2A-G, as well as the structural embodiments in FIGS. 3B and 4B.

Depending on the particular embodiment of the invention, the amount and type of gases in the gas mixture used for etching can vary. That is, the flow rates of the gases used can vary within ranges with different embodiments of the method 200, as well as during particular portions of the etch processes. For example, the types and the amounts of gases used during a main etch, or ME, of the dielectric can vary greatly from those used during other stages of the etching process, such as during an open etch or an over etch, as further detailed herein. In certain embodiments, fluorocarbons, hydrogen-free fluorocarbons and/or hydrofluorocarbons can be used with hydrogen during etching. The particular amounts of hydrogen, fluorocarbon, hydrogen-free fluorocarbon, hydrofluorocarbon, and/or other gases, used during any stage of etching can vary depending on the embodiment of the method.

In some embodiments, during the etching, the range of the flow rate of hydrogen, or H₂, is between about 10 standard cubic centimeters per minute, or sccm, and about 250 sccm. However, as further detailed herein, in some embodiments of the method, the etch is performed with flow rates of H₂ at, or about, 40 sccm, 60 sccm, and 75 sccm for trench etching and at, or about, 200 sccm for via etching. The hydrogen gas can be a non-etchant gas.

The etching gas mixture can also include a fluorocarbon or a hydrogen-free fluorocarbon gas, depending on the particular embodiment. The amount of fluorocarbon or hydrogen-free fluorocarbon applied can vary, but in certain embodiments the flow can range from about 20 sccm to about 200 sccm. The fluorocarbon or hydrogen-free fluorocarbon gas can be a CₓF_{y} gas (wherein x can include x=1, 2, 3 . . . , and y can include y=1, 2, 3 . . . ). Some examples of this fluorocarbon or hydrogen-free fluorocarbon gas include a gas from a group including CF₄, C₂F₂, C₂F₄, C₃F₆, C₄F₆, C₄F₈, C₅F₈, C₆F₆, and the like. For instance, as shown wherein with examples of embodiments, the hydrogen-free fluorocarbon gas used is a CF₄ gas with a flow rate at, or about, 100 sccm for trench etching and at, or about, 60 sccm for via etching. The fluorocarbon or hydrogen-free fluorocarbon gases can be part of the etchant gas.

Depending on the embodiment, the etch gas mixture can also include a hydrofluorocarbon gas. With some embodiments, the amount of hydrofluorocarbon can range from about 20 sccm to about 200 sccm. The hydrofluorocarbon gas can be a CₓH_{y}F_{z} (wherein x can include x=1, 2, 3 . . . , y can include y=1, 2, 3 . . . , and z can include z=1, 2, 3 . . . ). Examples of such a hydrofluorocarbon gas can include a gas from a group including C₂HF₅, CHF₃, CH₂F₂, CH₃F, C₃H₂F₆, C₃H₂F₄, C₃HF₅, C₃HF₇, and the like. As set forth in further detail herein, an example of an embodiment using a hydrofluorocarbon gas is using a CH₂F₂ gas with a flow rate at, or about, 10 sccm for etching a via with other gases including fluorocarbon gases. The hydrofluorocarbon gas can be part of the etchant gas.

In some embodiments, the etching gas mixture includes both hydrogen-free fluorocarbon and hydrofluorocarbon gases. Such a combination gas can, in certain embodiments range in flow between about 10 sccm to about 200 sccm, with the ratio of hydrogen-free fluorocarbon to hydrofluorocarbon ranging from about 0 to about 1, depending on the specifics of the particular embodiment. A combination hydrogen-free fluorocarbon/hydrofluorocarbon gas includes a combination of two or more gases selected from the group of C_{x′}F_{y′} (wherein x′ can include x′=1, 2, 3 . . . , and y′ can include y′=1, 2, 3 . . . ) and C_{x″}H_{y″}F_{z″} (wherein x″ can include x″=1, 2, 3 . . . , y″ can include y″=1, 2, 3 . . . , and z″ can include z″=1, 2, 3 . . . ). Specific examples of a combination hydrogen-free fluorocarbon/hydrofluorocarbon gas includes CF₄/C₄F₈/CH₂F₂, C₄F₆/CHF₃, C₄F₈/CHF₃ C₄F₆/CH₂F₂, and the like. As described in further detail herein, some embodiments use a combination of CF₄ gas at, or about, 60 sccm and C₄F₈ gas at, or about, 15 sccm for via etching, and in another example a combination of CF₄ gas at, or about, 60 sccm, C₄F₈ gas at, or about, 15 sccm, and CH₂F₂ at, or about, 20 sccm also for via etching.

Depending on the embodiment, the ratio of the flow of hydrogen gas or non-etchant gas to the flow of the hydrogen-free fluorocarbon, hydrofluorocarbon gas or etch gas can vary. In certain embodiments, the ratio is between about 0.3 and about 0.5.0 and in others between about 0.6 and 2.7. In some embodiments having hydrogen and hydrogen-free fluorocarbon gases the ratio can range between about 0.3 and about 2.7. In some embodiments having hydrogen, hydrogen-free fluorocarbon and hydrofluorocarbon gases, the ratio can range between about 0.55 and about 2.1. As shown with the flow rates in the examples herein, some example ratios include about 0.36, 0.56, 0.6, 0.75, 1.11, 2.11 and 2.67. Of course other ratios are possible depending on the flow rates of the various gases.

In certain embodiments, the etching gas mixture can further include an inert gas or inert gases. Examples of such inert gases include any selected from a group including He, Ne, Kr, Xe and Ar, and the like. In some embodiments, an Argon, or Ar, gas is used in the gas mixture at flow rates between about 0 sccm to about 600 sccm. As further detailed herein, with certain particular embodiments Ar flow rates of at, or about, 200 sccm for trench etching and at, or about, 600 sccm for via etching are used.

The gas mixture can also include, in embodiments, a nitrogen, or N₂, and/or a carbon monoxide, or CO gas. In some embodiments, the flow rate of the N₂ gas is between about 0 sccm to about 200 sccm. As further detailed herein, with certain embodiments having the N₂ gas flow rate at, or about, 100 sccm for trench etching and at, or about, 50 sccm for via etching. In some embodiments, flow rate of the CO gas is between about 100 sccm to about 600 sccm.

Depending on the embodiment of the method, the gas mixture used during etching can be any one, or a combination of gases, set forth herein. For example, in at least one embodiment the gas mixture can include: H₂ at a flow rate between 25 sccm and 250 sccm; CₓF_{y}, or a combination of two or more selected from CₓF_{y} and CₓH_{y}F_{z}, at a flow rate between 20 sccm and 200 sccm; Ar at a rate between 100 sccm and about 600 sccm, and N₂ at a rate between 0 sccm and 200 sccm.

The type of feature etched can determine the types of gases and their flow rates used during the etch. In some embodiments, for etching trenches and/or larger open areas, the gas mixture used is of a leaner chemistry. In other embodiments, for etching vias, the gas mixture used is of a richer chemistry. For instance, for trench etching a low carbon gas such as CF₄, is used, in contrast, for via etching higher carbon containing gases, such as C₄F₈ and CH₂F₂, are used. Leaner chemistries provide for less polymer formed during etches where more material is removed, such as with trenches or other large open areas. Richer chemistries aid etching by providing higher selectivities to the PR and barrier layers.

The flow chart of FIG. 2B shows the step of applying a gas mixture including hydrogen 230, can include applying additional gases to the gas mixture. Namely, the applying step 230 can also include wherein the hydrogen is a hydrogen gas 231, wherein the gas mixture further includes a hydrogen-free fluorocarbon gas 232, wherein the gas mixture further includes a hydrofluorocarbon gas 233, wherein the gas mixture further includes a hydrogen-free fluorocarbon and a hydrofluorocarbon gas 234, wherein the gas mixture further includes an inert gas 235, wherein the gas mixture further includes a nitrogen gas 236, and wherein the gas mixture further includes a carbon monoxide gas 237.

The step wherein the hydrogen is a hydrogen gas 231, as shown in FIG. 2C, can include additional steps. Namely, these steps can include wherein the hydrogen gas is applied at a flow rate between about 10 sccm and about 250 sccm 231a, and wherein the hydrogen gas flow rate is between about 10 sccm and about 75 sccm 231b. In at least one embodiment, the step 231b is a reduced hydrogen etch, as described further herein.

As shown in FIGS. 2B and D, the step wherein the gas mixture further includes a hydrogen-free fluorocarbon gas 232, as shown with 232a the hydrogen-free fluorocarbon gas can be a CₓF_{y} gas (where x=1, 2, 3 . . . , and y=1, 2, 3 . . . ), and as shown in 232b, be applied at a flow rate between about 20 sccm to about 200 sccm. As noted, CₓF_{y} gas can include one or more of CF₄, C₂F₂, C₂F₄, C₃F₆, C₄F₆, C₄F₈, C₅F₈ and C₆F₆.

Likewise, as shown in FIGS. 2B and E, With the step wherein the gas mixture further includes a hydrofluorocarbon gas 233, the hydrofluorocarbon gas can, as shown with 233a be a CₓH_{y}F_{z} gas (where x=1, 2, 3 . . . , y=1, 2, 3 . . . , and z=1, 2, 3 . . . ), which can be applied at flow rates between about 20 sccm to about 200 sccm, as shown in 233b. The CₓH_{y}F_{z} gas can include one or more of C₂HF₅, CHF₃, CH₂F₂, CH₃F, C₃H₂F₆, C₃H₂F₄, C₃HF₅, and C₃HF₇.

The step wherein the gas mixture further includes a hydrogen-free fluorocarbon and a hydrofluorocarbon gas 234, as shown in FIGS. 2B and F, the hydrogen-free fluorocarbon gas and a hydrofluorocarbon gas can be a C_{x′}F_{y′}/C_{x″}H_{y″}F_{z″} gas (where x′=1, 2, 3 . . . , y′=1, 2, 3 . . . , x″=1, 2, 3 . . . , y″=1, 2, 3 . . . , and z″=1, 2, 3 . . . ), as shown in 234a. Also, the flow rate of the hydrogen-free fluorocarbon gas and a hydrofluorocarbon gas can be between about 10 sccm to about 200 sccm, as shown in 234b. The C_{x′}F_{y′}/C_{x″}H_{y″}F_{z″} gas can include CF₄/C₄F₈/CH₂F₂, C₄F₆/CHF₃, C₄F₈/CHF₃, and C₄F₆/CH₂F₂.

The gases used can be applied either as a preformed mix of the gas components, as a partial mixture of more than one component, or as individual components to mix in the chamber. One or more flows of gases, i.e. a double flow, can be employed to deliver the gases. Mixing the gases prior to being introduced into the chamber allows a showerhead, or similar device, to be used.

As noted, FIGS. 3B and 4B show embodiments of structures which can be etched by the present invention. As shown, in FIG. 3B a region 340 is defined above and about the structure 300 wherein the etching gas mixture can be applied to facilitate etching of the structure 300. Likewise, in FIG. 4B a region 460 is defined above the structure 400 where the etching gas mixture can be applied.

The pressure of the gas mixture can also range in value depending the embodiment. For some embodiments, the pressure can range from about 5 millitorr, mT or mTorr, to about 400 mTorr. In certain embodiments, as further detailed herein, the pressure is at, or about, 20 mTorr to at or about 30 mTorr for trench etches and at, or about, 40 mTorr for a via etch.

Some embodiments of the present invention employ relatively low pressures for both trench and via etching. In such embodiments the pressure ranges from 5 to 30 mTorr for types of etching.

The pressure ranges and values set forth above are for a wafer sized at, or about, 300 mm in diameter, for wafers of other sizes the values are adjusted accordingly. In some embodiments employing a 200 mm wafer, the pressure is about the same as that used for the 300 mm wafer etch.

In some embodiments of the invention, as shown in FIG. 2G, the step of applying a gas mixture including hydrogen 230 can include the step wherein the gas mixture is applied at a pressure between about 5 mTorr and about 400 mTorr 238. The step 238 in turn can include the step wherein the gas mixture is applied at a pressure between about 5 mTorr and about 30 mTorr 238a. The step 238 a can be employed for embodiments with relatively low pressure etching.

The step of forming plasma 240 of the fabrication method 200 is set forth in FIGS. 2A and H. During the step 240 the plasma is formed with a particular source power and bias power depending on the embodiment.

As described further herein, the particular level or range of levels that the source power and the bias power can be set at, is dependent, at least in part, on the size of the wafer used. Generally, the greater the diameter of the wafer, the greater the bias level, and the greater the volume of the chamber, the greater the source level. Most ranges and values set forth herein are for wafers 300 mm in diameter, for wafers of other sizes the values would be adjusted accordingly. For example, the bias settings for a 200 mm diameter wafer will be about half of the value used for 300 mm wafers, but the source would be generally similar between a 200 mm wafer and a 300 mm wafer.

In some embodiments, the density, or electron density, can range from about 5×10⁹ to about 5×10¹¹ electrons/cm³ and above, including about 5×10¹⁰ electrons/cm³ and above. Of course, other ranges of the electron density are also usable in other embodiments.

In certain embodiments of the present invention, the source power setting during the main etch can be within the range of about 0 Watts to about 2000 Watts, where some embodiments employ a source level of at, or about, 0 Watts and at, or about, 200 Watts. The use of source power can aid in opening up the feature being etched and prevent, or reduce, etch stop.

For some embodiments, the RF bias can be set between about 300 Watts to about 3000 Watts for the main etch, and as described herein, with some cases having RF bias settings of at, or about, 900 Watts and 1500 Watts for trench etching and at, or about, 1100 Watts for via etching. For some embodiments etching a 200 mm wafer, the bias power can be between 150 Watts and 1500 Watts, with certain cases having a bias of ranging between 450 Watts to 1500 Watts. The frequency of the bias power can vary depending on the embodiment, with at least one embodiment operating at, or about, 13.56 MHz.

The operation temperature during etch can in some embodiments range from about −20 C to about 40 C, with certain embodiments having a cathode temperature at 20 C for trench etching and 25 C for via etching, as described herein.

Any of a variety of etching tools can be used to etch according to one or more embodiments of the present invention, including a dual frequency enabler or a dielectric etch enabler. Examples of usable tools include the APPLIED CENTURA ENABLER ETCH, APPLIED ENABLER ETCH and the APPLIED PRODUCER ETCH, which are each available from Applied Materials, Inc. of San Jose, Calif. Usable tools include that set forth in U.S. patent application Ser. No. 10/192,271, entitled CAPACITIVELY COUPLED PLASMA REACTOR WITH MAGNETIC CONTROL, by Hoffman et al., filed Jul. 9, 2002, which is hereby incorporated by reference in its entirety.

Of course, similar tools manufactured by Applied Materials or other manufacturers can be used as well. Typically, the tool used will have to be tuned to account for the differences from the tools set forth herein, and to account for factors including the particular bias and source frequencies of the tool, wafer size and the like. Also, the chemistries may have to be adjusted depending on the specific volume of the chamber. Such tuning and adjustments can be made by one skilled in the art.

Each of the particular etching tools available from Applied Materials, as listed above, have controls including a Neutral Species Tuning Unit or NSTU, and a Charged Species Tuning Unit or CSTU. The NSTU and CSTU controls are used for uniformity tuning, which, among other things, allow independent control of etch rate and critical dimension, or CD, uniformities. The CSTU includes inner (I) and outer (o) settings that control the etch rate uniformity, while the NSTU sets the flow pattern of the gases, i.e. from a showerhead in the chamber. Being able to set the pattern of the flow allows more uniformity in the process. The gases of the gas mixture can be mixed prior to being distributed by the showerhead.

As shown in the flowchart of FIG. 2H, the step of forming a plasma 240 can include where the plasma is formed with a source power between 0 Watts and 2000 Watts 242, where the plasma is formed with a RF bias between 300 Watts to 3000 Watts 244, where the plasma has an electron density of about 5×10⁹ electrons/cm³ to about 5×10¹¹ electrons/cm³ and above 246, and where the plasma is formed with one or more frequencies 248. The step 242 can further include with a source power of 0 Watts 243a and with a source power of 200 Watts 243b. The step 244 can further include the RF bias power is 900 Watts 245a, the RF bias power is 1100 Watts 245b, and the RF bias power is 1500 Watts 245c. The step 246 can include where the plasma has an electron density greater than 5×10¹⁰ electrons/cm³ 247. The step where the plasma is formed with one or more frequencies 248 can include frequencies 2 MHz 249a and 13.56 MHz 249b, depending on the embodiment.

In certain embodiments, the plasma is formed at a frequency of at, or about, 13.56 MHz. In other embodiments, the plasma is formed with more than one frequency including at, or about 2 MHz and at, or about 13.56 MHz. Also, the distribution of the power at each frequency can vary. For instance, in some embodiments, the bias power used can be a combination of 50% 2 MHz bias and 50% 13.56 MHz bias. To provide more than one frequency, a tool such as an APPLIED DFB ENABLER ETCH tool, which is available from Applied Materials, Inc. of San Jose, Calif., U.S.A., can be used with some embodiments.

As shown in FIGS. 2A, I and J, 3C and 4C-E, another step in the method 200 is etching the etch material 250. During this step an opening is defined in the etch material by using a gas mixture containing hydrogen.

Factors including the etch rate, duration of etch, depth and profile of the etched opening, selectivity and etch stop, can vary depending on the particular embodiment of the method. That is, the particular value and/or range of these factors will vary depending on items including the layering of the structure etched, the particular dielectric used, the type, if any, of anti-reflective coating, the type, if any, of the barrier layer, the source power levels, the bias power levels, the composition and concentrations of the gas mixture, the wafer diameter, and the like.

The duration of the etch can vary depending on the embodiment of the method 200. In some embodiments, the duration ranges from about 40 seconds to about 70 seconds. Certain embodiments have a duration of about 40 second and 70 seconds for the main etch for trench etching and about 60 seconds for the main etch for via etching.

The resulting depth and profile of the opening creating by the etch can vary depending on the embodiment. For example, the opening may be made deeper for a via, or wider for a trench, and in some circumstances have slanted or vertical sidewalls. While it is typically desired to minimize, or eliminate the taper of the vias, taper in the trench profile is typically not an issue as trenches are usually used to electrically isolate the die region and not normally for an interconnect.

Selectively of the etch can vary as well depending on the embodiments. The selectivity of the etch rate of the dielectric to the etch rate of the photoresist can range between 1 to infinity. In some embodiments the photoresist selectivity is about 5.

Depending on the embodiment, all of the etching of the structure can be performed in the etch step 250, or in some cases, in one or more additional etch steps. These additional etch steps can include steps such as ARC open etch or over etch.

As shown in FIG. 2J, in certain embodiments, the step 250 includes single step etching 251 and multiple step etching 254. The single step etching 251 can include etching an ARC and a dielectric with a single chemistry 252, which in turn can include etching a trench 253. The multiple step etching 254 can include etching a via 255.

Single Step Etching:

In embodiments of the present invention where the etched structure has an ARC layer that is etchable by the same chemistry as that used to etch the dielectric layer, a single etch step can be used. An example of an ARC layer etchable by the same chemistry is a DUO ARC, as described herein. The structure 300 of FIG. 3 can include an ARC which can be etched by the same chemistry as that used to etch the dielectric.

The structure 300 as etched is shown in FIG. 3C, having a formed an opening 350. Depending on the embodiment, this etching can be by a single etch step using a single chemistry to etch through both the ARC 320 and the dielectric layer 310. The opening 350 is positioned extending downward from the gap 332, through the ARC layer 320 and into the dielectric material 310. The specific size (e.g. depth) and shape of the resulting opening 350 is dependent on various factors including, the size and position of the photoresist gap 332, the type of the ARC 320 and the dielectric 310, the source power levels, the bias power levels, the gas mixture, and the duration of the etching. Depending on the particular application, the opening 350 can be formed into any of a variety of configurations including a via or a trench. However, with the use of an ARC, such as DUO, for single stage etching of the opening 350, the opening is typically a trench.

In embodiments where trench etching is performed with single stage etching, relatively low gas pressures ranging from 5 to 30 mTorr can be used.

Examples of embodiments of the present invention are set forth below. Examples 1, 2 and 6 etch common structures, as detailed below. The structure provided for each of these etch examples is on a 300 mm diameter wafer with a layering as shown in FIG. 5. The etch structure 500 includes an inter-level dielectric (ILD) layer 510, a DUO anti-reflective layer 520 over the ILD layer 510, and a photoresist layer or PR 530 on top of the DUO ARC layer 520. In each of the examples the dielectric material of the ILD layer 510 is low-k film carbon doped silicon oxide. The DUO ARC 520 is deposited on the ILD layer 510 to reduce reflections during the lithography exposure. The photoresist 530 used is TOK7A7O a 193 nm photoresist, which is available from TOK, Tokyo Ohka Kogyo Co., Ltd. of Kawasaki City, Japan. The etching tool used to perform the etch in each of Examples 1 through 8 is an APPLIED ENABLER ETCH tool, which is described above.

### EXAMPLE 1

One example of an embodiment of the present invention includes etching a trench structure with a gas mixture containing hydrogen or H₂, tetrafluoromethane or CF₄, nitrogen or N₂, and argon or Ar.

As noted herein, the structure etched has a layering as set forth in the structure 500 in FIG. 5.

During the etching, the gas mixture applied has gas flows of 60 sccm of H₂, 100 sccm of CF₄, 100 sccm of N₂ and 200 sccm of Ar, at a pressure of 30 mTorr.

The plasma formed for the etch has the bias at 900 Watts and the source at 0 Watts. The APPLIED ENABLER ETCH tool is used with the structure is etched for 40 seconds.

### EXAMPLE 2

Another trench etching embodiment of the present invention includes etching a trench structure with a gas mixture containing H₂, CF₄, N₂, and Ar. An etched structure resulting from this example is shown in the rendering of the cross-section of FIG. 6.

As noted herein, the structure etched has a layering as set forth in the structure 500 in FIG. 5.

The gas mixture is applied at the gas flows of 75 sccm of H₂, 100 sccm of CF₄, 100 sccm of N₂ and 200 sccm of Ar, at a pressure of 20 mTorr.

With the gas applied, the plasma formed for the etch has the RF bias at 13.56 MHz at 1500 Watts and the source at 0 Watts. The APPLIED ENABLER ETCH tool has the NSTU set at 2.0, the CSTU inner/outer (i/o) set at 0/0, and the wafer/chuck cooling Helium (He) inner/outer (in-out) pressures are 10T-10T.

Once the plasma is formed the structure is etched for 70 seconds, at a cathode temperature or Tcath of 20 C, and with the conditions listed above.

The results of the etch for this example is shown in FIG. 6. As shown in FIG. 6, a structure 600 has been etched to define trenches 640. The structure 600 includes an ILD layer 610, a BARC layer 620 is on the ILD layer 610, and a PR layer 630 is on top of the BARC layer 620.

In this example, the photoresist selectivity is 8. This selectivity is greater than that obtained from other processes wherein the typical photoresist selectivity is about 1.

As shown in the example result of FIG. 6, the profile of some of the resulting trenches 640, have slightly tapered to nearly vertical sidewalls 642 and flat bottoms 644, as shown in FIG. 6. Some of the bottom surfaces 644 have small indentations 646 near the sidewalls 642, which are caused by a small amount of micro-trenching.

Multiple Step Etching:

For embodiments which can not be effectively and/or efficiently etched by a single chemistry, additional etch steps can be added to the method 200. Such not effective and/or efficient etching can include where the single chemistry has an unacceptably long duration for etching through all the layers and/or where the etch quality is unacceptably low. With embodiments where the etched structure have an ARC that needs to be etched by a separate etch chemistry, then the method 200 can include etching an ARC layer step 220, as shown in FIG. 2I. This etching step 220 can be a breakthrough etch, an arc open etch, an arc etch, a cap etch or the like.

Depending on the embodiment, a variety of gases can be used during the arc open etch. One such gas is CF₄ with a flow rate of between about 50 sccm and about 400 sccm, with certain embodiments having a rate at, or about, 150 sccm. Another usable gas a trifluoromethane, or CHF₃, gas with a flow rate of between about 0 sccm and about 400 sccm, and in some embodiments a flow rate at, or about, 30 sccm. Yet another gas for the arc open etch is an N₂ gas with a flow rate from about 0 sccm to about 400 sccm, with particular embodiments having a flow rate of, at or about, 0 sccm. An Ar gas can be included in the gas mixture at a flow rate ranging from about 0 sccm to about 400 sccm, with some embodiments at, or about, 0 sccm.

The pressure of the gas mixture during the arc open etch with a 300 mm wafer can range from about 30 mTorr, to about 400 mTorr, and in certain embodiments, the pressure is set at, or about, 300 mTorr for the arc open etch. For etching with wafers of other sizes the pressure values are adjusted accordingly. The manner and location of the gas application during an arc open etch can be as described for the main etch above.

The source power can be set during the arc open etch from 0 Watts to 300 Watts, with certain embodiments of the method having a level at, or about 0 Watts. The bias can be set for the arc open etch between 300 Watts and 2500 Watts with certain embodiments have a bias of 2000 Watts.

For embodiments of the present invention where the structure etched also includes a barrier layer that can not be effectively or efficiently etched to by the same chemistry used to etch the dielectric layer, the method 200 can also include a step of etching to a barrier layer 260, as shown in FIG. 2I. That is, in embodiments where the dielectric etch chemistries as set forth herein, will not selectively etch up to the barrier layer, but instead etch through the barrier, a separate etch chemistry can be used in the etching to a barrier 260. In some embodiments the etching of the dielectric material with the dielectric etch chemistry is terminated just prior to reaching the barrier. Then, the barrier etch chemistry which has a higher selectivity to the barrier is used to etch up to the barrier.

Etching to a barrier layer 260 can include one or more over etch steps performed after the main etch as required by the embodiment. In some embodiments the over etch chemistry lacks hydrogen in the gas mixture. A transition step after the main etch but prior to the over etch or etches can be used to remove the hydrogen from the chamber to prevent etching through the barrier.

In some embodiments, the over etch step has a gas mixture which includes between about 6 sccm and about 20 sccm of C₄F₆, with certain embodiments having a rate at, or about, 13 sccm and 17 sccm, between about 0 sccm and about 400 sccm of N₂, with embodiments at, or about, 200 sccm, and between about 0 sccm and about 800 sccm of Ar, with embodiments at, or about, 300 sccm, and for a 300 mm wafer pressures of between about 5 mTorr and about 60 mTorr, with embodiments at, or about, 20 mTorr. The bias is between 1000 Watts and 3500 Watts, with embodiments at 3000 Watts, and the source between 0 Watts and 300 Watts, with embodiments at 0 Watts.

It should be clear that other over etch steps with a variety of variable values, other than those set forth in the examples above, can be used in embodiments of the present invention.

FIG. 4 shows the structure 400, which can be used in multiple etch step embodiments of the method of the present invention. The structure can include ARC layers 440 and a barrier layer 420, which can not be efficiently and/or effectively etched by the same chemistry as that is used to etch the dielectric layer 430. As shown in FIGS. 4C-E, openings 470 are formed in the structure 400.

The openings 470 are positioned extending downward from the gap 452, and depending on the stage of the etch can extend through the anti-reflective layers 440 and the dielectric material 430 to the barrier 420. The specific size (e.g. depth) and shape of each resulting opening 470 is dependent on various factors including, the size and position of the photoresist gap 452, the type of ARC 440 and dielectric 430, the source power levels, the bias power levels, the gas mixture, and the duration of the etching. Depending on the particular application, the opening 470 can be formed into any of a variety of configurations including a via or a trench. However, with the use of an ARC and barrier layers in multiple stage etching, typically is a via formed.

In at least one embodiment, the step of etching an ARC layer 220, can provide a result such as that shown in FIG. 4C. As shown the opening 470 has been etched through the ARC 440 and into a portion the dielectric 430 to form an opening 472. Next, the steps of applying a gas mixture 230, forming a plasma 240 and etching the etch material 250, can be performed to etch the dielectric 430, as shown in the embodiment of FIG. 4D. As shown, the opening 470 has been extended downward to end just prior to the barrier 420, forming an opening 474. A dielectric portion 432 of the dielectric 430 remains just over the barrier 420. The portion 432 acts to protect the barrier 420 and prevent any premature etching of the barrier 420 by the etch chemistry used to etch the dielectric 430. The size of the portion 432 can vary depending on the embodiment of the method 200. The step of etching to a barrier 260 can then be performed to form the opening 476 which extends to the barrier 420 as shown in FIG. 4E.

It should be noted that with embodiments having a BARC or DARC material layer and/or a barrier layer can have these layers etched by a hydrogen containing gas mixture used to etch the dielectric, such as with a single stage etching, but with increased etch time and/or reduced etch profiles.

In embodiments where via etching is performed with multiple stage etching, relatively low gas pressures ranging from 5 to 30 mTorr can be used.

Examples 3-5 and 7-8 below set forth examples of embodiments of the method of the present invention wherein vias are etched into a layered structure.

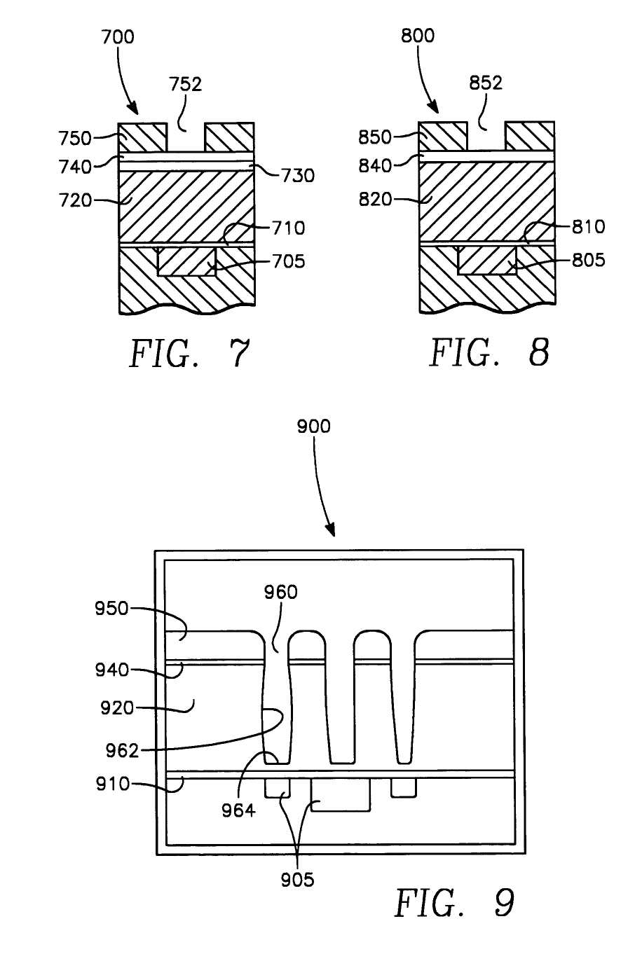

Common to Examples 3 and 5 is the structure which is etched. These structures are on a 300 mm diameter wafer with a layering as shown in FIG. 7. The etch structure 700 includes a line 705, a barrier layer 710 positioned over the line 705, an inter-level dielectric (ILD) layer 720, above the barrier layer 710, a dielectric anti-reflective layer or DARC layer or SiO2 cap layer 730 over the ILD layer 720, a bottom anti-reflective layer or BARC 740 on the DARC layer or SiO2 Cap layer 730, and a photoresist layer or PR 750 on top of the BARC layer 740. In each of the examples the line 705 is a copper or Cu, the barrier layer 710 is a SiCN, BLOK II, SiC, BLOK III or a low k or porous barrier material, which functions as an etch stop. The dielectric material of the ILD layer 720 is low-k film carbon doped silicon oxide. The BARC layer is a standard organic anti-reflective layer 740 while the DARC layer or SiO₂ Cap layer 730 are inorganic layers. Namely, the BARC is BREWER ARC 29A available from Brewer of Rolla, Mo. and the DARC is SION available from Applied Materials of San Jose, Calif. The BARC and DARC are deposited on the ILD layer 720 to reduce reflections during the lithography exposure. The cap layer 730, which can include SiO2, SiC, and Si3N4 is used to increase mechanical strength to the low k structure to withstand CMP planarization. The photoresist used is TOK7A7O a 193 nm photoresist, which is available from TOK, Tokyo Ohka Kogyo Co., Ltd. of Kawasaki City, Japan. The etching tool used to perform the etch in each example set forth below is an APPLIED ENABLER ETCH tool, which is described above.

Example 4 uses a similar structure as the structure 700, except without the DARC or cap layer, as detailed below.

### EXAMPLE 3

An example of an embodiment of the present invention for via etching includes etching a structure with a gas mixture containing H₂, CF₄, octafluorocyclobutane or C₄F₈, N₂, and Ar.

The structure provided for the etch is arranged as shown in FIG. 7 with elements as set forth herein. An APPLIED ENABLER ETCH tool is used to etch the structure.

In this particular example, based on the structure 700 of FIG. 7, a BARC layer 740 and a cap layer 730 are first opened, then the main etch is performed to etch the dielectric layer 720. The gas mixture applied during the main etch includes gas flows of 200 sccm of H₂, 60 sccm of CF₄, 15 sccm of C₄F₈, 50 sccm of N₂ and 600 sccm of Ar, at a pressure of 40 mTorr. The plasma formed for the etch has the bias at 1100 Watts and the source at 0 Watts.

### EXAMPLE 4

Another example of an embodiment of the present invention for via etching includes etching a structure with a gas mixture containing H₂, CF₄, C₄F₈, CH₂F₂, N₂, and Ar. Results of this example are shown in the rendering of FIG. 9.

As noted, the structure of Example 4 is similar to the structure used in Examples 3 and 5, except that the DARC or cap layer is not present. As shown in FIG. 8, the structure 800 includes a line 805, a barrier layer 810 positioned over the line 805, an inter-level dielectric (ILD) layer 820, above the barrier layer 810, a bottom anti-reflective layer or BARC 840 on the ILD layer 820, and a photoresist layer or PR 850 on top of the BARC layer 840. Otherwise, each of these layers are as described above in the structure 700. An APPLIED ENABLER ETCH tool is used to etch the structure. In this example, the BARC layer 840 can be opened by any known process or by any method set forth herein. The remainder of the etch is performed in separate steps as set forth herein.

The main etch is performed to etch the dielectric. The gas mixture applied during the main etch includes gas flows of 200 sccm of H₂, 60 sccm of CF₄, 15 sccm of C₄F₈, 20 sccm of CH₂F₂, 50 sccm of N₂ and 600 sccm of Ar, at a pressure of 40 mTorr. The plasma formed for the etch has the bias at 1100 Watts and the source at 200 Watts. The APPLIED ENABLER ETCH tool has the NSTU set at 4, the CSTU outer is set at 5, and the wafer/chuck cooling Helium (He) inner/outer (in-out) pressures are 15 T-15 T. The structure is etched for 60 seconds, with a cathode temperature of 25C. At the end of the main etch the etch terminates just prior to reaching the barrier 810.

Next, a series of transition steps are performed prior to an over etch step. The first transition step has a flow of 300 sccm of Ar at 30 mTorr, a bias of 300 Watts and a source of 0 Watts. The ENABLER ETCH tool has the NSTU set at 1.35, the CSTU outer set at 0, and the wafer/chuck cooling Helium (He) inner/outer (in-out) pressures are 15T-15T. The cathode temperature is 25C and the duration of the first transition is 5 seconds.

The second transition step has a flow of 15 sccm of C₄F₆, 0 sccm of N₂, 200 sccm of Ar at 30 mTorr, a bias of 3000 Watts and a source of 0 Watts. The ENABLER ETCH tool has the NSTU set at 9, the CSTU outer set at 2, and the He inner/outer pressures are 15T-15T. The cathode temperature is 25C and the duration of this transition is 5 seconds.

The third transition step has a flow of 15 sccm of C₄F₆, 50 sccm of N₂, 200 sccm of Ar at 30 mTorr, a bias of 3000 Watts and a source of 0 Watts. The ENABLER ETCH tool has the NSTU set at 9, the CSTU outer set at 2, and the He inner/outer pressures are 15T-15T. The cathode temperature is 25C and the duration of this transition is 10 seconds.

Next, to etch to the barrier 810 an over etch or OE step is used with a gas mixture which includes 15 sccm of C₄F₆, 225 sccm of N₂ and 200 sccm of Ar, at a pressure of 30 mTorr. The bias is 3250 Watts and the source at 0 Watts. The APPLIED ENABLER ETCH tool has the NSTU set at 9, the CSTU inner/outer (i/o) set at 0/2, and the wafer/chuck cooling Helium (He) inner/outer (in-out) pressures are 15T-15T. The etching duration is 80 seconds, with the cathode temperature of 25C.

The photoresist 850 is removed in an ashing step. During this step the gas mixture includes 500 sccm of O₂ at a pressure of 10 mTorr. The bias is 200 Watts and the source is at 100 Watts. The APPLIED ENABLER ETCH tool has the NSTU set at 2.4, the CSTU inner is set at 14, and the wafer/chuck cooling Helium (He) inner/outer (in-out) pressures are 15T-15T. The etching duration is 45 seconds, with the cathode temperature of 25C.

The results of the etch for this example is shown in FIG. 9. As shown, a structure 900 has been etched to define vias 960. The structure 900 includes a line 905, a barrier layer 910, an ILD layer 920 is position above the barrier layer 910, a BARC layer 940 is on the ILD layer 920, and a PR layer 950 is on top of the BARC layer 940.

In this example, the photoresist selectivity is infinity. This selectivity is greater than that obtained from other processes wherein the typical photoresist selectivity is about 3 to 5.

As shown, the profile of the resulting vias 960 has vertical sidewalls 962 and flat bottoms or stops 964.

### EXAMPLE 5

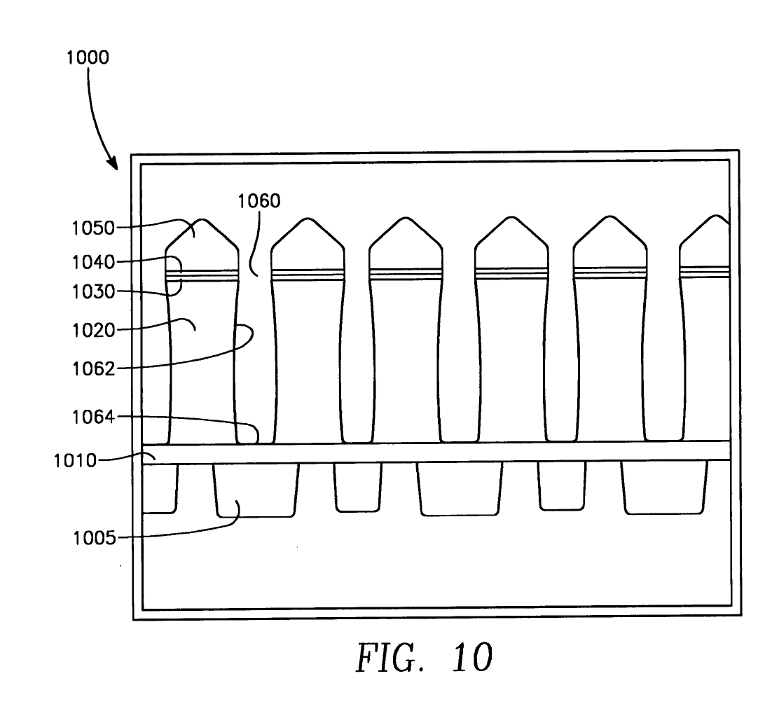

An example of an embodiment of the present invention includes etching a via structure with a gas mixture containing H₂, CF₄, C₄F₈, difluoromethane or CH₂F₂, N₂, and Ar. An etched structure resulting from this example is shown in the rendering of the cross-section in FIG. 10.

The first step of the etching process of this example is to provide a structure to be etched, as shown in FIG. 7 and described above. The structure is etched in an APPLIED ENABLER ETCH tool.

Again, with the structure 700 of FIG. 7 including a BARC layer 740 and a DARC layer 730 positioned over the dielectric layer 720 and the barrier 710 below the dielectric 720, the etch is performed in separate steps.

The first of these etch steps is a breakthrough or arc open etch where the ARC layers are etched through to allow for later etching of the dielectric layer. With the ARC opened the main etch is performed to etch the dielectric. The gas mixture applied during the main etch includes gas flows of 200 sccm of H₂, 60 sccm of CF₄, 15 sccm of C₄F₈, 20 sccm of CH₂F₂, 50 sccm of N₂ and 600 sccm of Ar, at a pressure of 40 mTorr. The plasma formed for the etch has the RF bias at 13.56 MHz at 1100 Watts and the source at 200 Watts. The APPLIED ENABLER ETCH tool has the NSTU set at 2, the CSTU inner set at 5, and the wafer/chuck cooling Helium (He) inner/outer (in-out) pressures are 15T-15T. Once the plasma is formed the structure is etched for 60 seconds, at a cathode temperature or Tcath of 25 C, and with the conditions listed above, with the etch terminating just prior to reaching the barrier 810.

Next, to etch to the barrier 710 an over etch or OE step is used. After the main etch and a transition, two over etch or OE, steps are performed. In this example the transition is has a 300 sccm flow of Ar at a pressure of 20 MTORR with a bias of 300 Watts, a source of 0 Watts, a NTSU of 1.35, CSTUO of 0, He in-out of 15-15, cathode temp of 25 C for a duration of 5 seconds. The first over etch step of this example includes flows of 13 sccm of C4F6, 200 sccm of N2, 300 of Ar, bias of 3000 Watts, a source of 0 Watts, a pressure of 20 mTorr, NSTU of 9, CSTUO of 1, He in-out of 15-15, cathode temp of 25 C for a duration of 35 seconds. The second over etch step of this example includes flows of 17 sccm of C4F6, 200 sccm of N2, 300 of Ar, bias of 3000 Watts, a source of 0 Watts, a pressure of 20 mTorr, NSTU of 9, CSTUo of 1, He in-out of 15-15, cathode temp of 25 C for a duration of 40 seconds.

The results of the etch for this example are shown in FIG. 10. As shown, a structure 1000 has been etched to define vias 1060. The structure 1000 includes lines 1005, a barrier layer 1010, an ILD layer 1020 is position above the barrier layer 1010, a DARC layer 1030 over the ILD layer 1020, a BARC layer 1040 on the DARC layer 1030, and a PR layer 1050 on top of the BARC layer 1040.

As shown in FIG. 10, the vias 1060 have sidewalls 1062 and bottoms or stops 1064 at the barrier layer 1010. The sidewalls 1062 have slight outward bowing and the bottoms 1064 are flat.

Reduced Hydrogen Flow Etch:

Relative to other embodiments of the present invention, some embodiments of the etching method have a reduced or lower hydrogen flow during the etch. Reducing the amount of the hydrogen gas flow during the etch provides better defined etch profiles, a greater retention of photoresist, less damage due causes such as striations and faster etching.

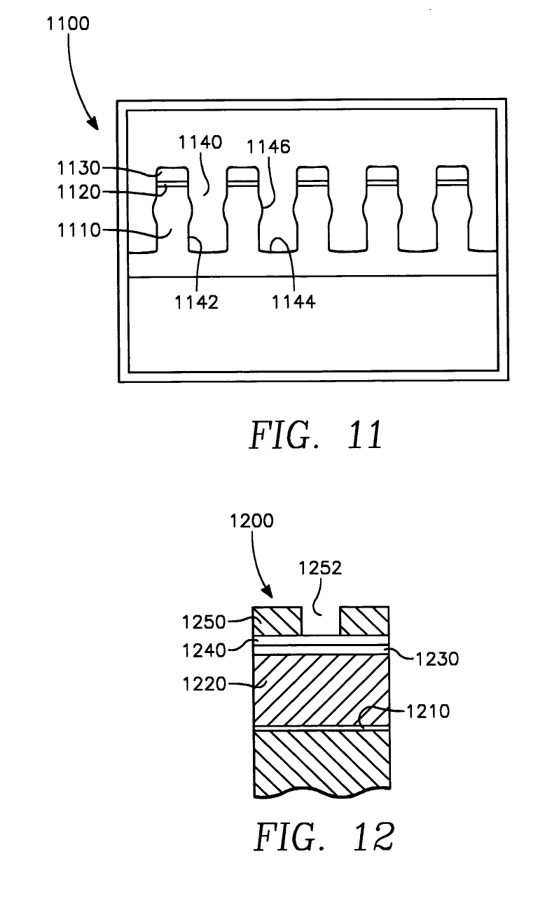

The etch profiles of the reduced hydrogen embodiments are well defined having, or at least tending to have, straighter and/or more vertical sidewalls and flatter bottom portions. As set forth in detail herein, examples of a reduced hydrogen flow etch are shown in FIGS. 11, 13 and 14. As shown the sidewalls of the features are straighter and more vertical than the sidewalls of features where higher flows of hydrogen were employed. Likewise, the bottom surfaces of the features are flatter and more uniform, than the bottoms surfaces of etch embodiments with higher hydrogen flows.

By having more vertical sidewalls the reduced hydrogen etching provides greater cross-sections for the material later deposited, which when conductive, such as copper, will benefit from reduced electrical resistance. Vertical sidewalls also allow for deeper trenches to be formed with higher aspect ratios. In turn, more vertical sidewalls allow for closer positioned etched features, increasing the density of features, and of the resulting devices. This has additional benefits for features such as vias, which are typically position in relatively close proximity to one another. Having etched features with flatter bottoms is important for dual damascene trench and desired for via processes. Both vertical sidewalls and flat bottoms reduce the potential for shorting or other problems associated with non-uniform and/or bowed surfaces.

The thickness of the photoresist still present after etching with reduced hydrogen flow embodiments are greater than the thicknesses remaining with other processes.

By retaining more of the photoresist the reduced hydrogen flow embodiments also provide greater protection to the structure underneath the photoresist. That is, effects such as striations and micro-loading which etch or deform the photoresist, will cause no, or reduced, damage to the underlying structure when more of the photoresist is retained during the etch. As shown in the examples below the photoresist is not damaged by striations or other such effects.

As noted above, in some embodiments of the present invention the flow rate of H₂, is between about 10 sccm, and about 250 sccm. In some embodiments having reduced hydrogen flow rates the flow rate is between about between about 10 sccm, and about 75 sccm. In certain reduced hydrogen flow embodiments the flow is 40 sccm and 50 sccm.

An example of an embodiment of an etch method with reduced hydrogen gas flow is set forth below in Example 6 for etching trenches and in Examples 7 and 8 for etching vias.

### EXAMPLE 6

In an example of an etching embodiment of the present invention, a gas mixture containing H₂, CF₄, N₂, and Ar is used, but with a reduced hydrogen gas flow relative to that set forth in other examples herein. An etched trench resulting from this example is shown in the rendering of the cross-section of FIG. 11.

The first step of the etching process of this example is to provide a structure to be etched. As with the prior examples, the etch structure employed in this example is that shown in FIG. 5, with the structure 500 and various layer and structures as set forth in detail above. Also, as noted the etching is performed in an APPLIED ENABLER ETCH tool.

To start the etching, the first step is to apply the gas mixture at the gas flows of 40 sccm of H₂, 110 sccm of CF₄, 100 sccm of N₂ and 200 sccm of Ar, at a pressure of 30 mTorr.

The plasma formed for the etch has the RF bias at 13.56 MHz at 1500 Watts and the source at 0 Watts. The APPLIED ENABLER ETCH tool has the NSTU set at 4.0, the CSTU inner/outer (i/o) set at 1.2/0, and the wafer/chuck cooling Helium (He) inner/outer (in-out) pressures are 10T-10T.

Once the plasma is formed the structure is etched for 40 seconds. The cathode temperature or Tcath is set during the etch at −20 C. The resulting etch rate being about 6000 Å/min.

The results of the etch for this example are shown in FIG. 11. As shown, a structure 1100 has been etched to define trenches 1140. The structure 1100 includes an ILD layer 1110, an ARC layer 1120 is over the ILD layer 1110, and a PR layer 1130 is on top of the ARC layer 1120.

In this example, the photoresist selectivity is about 5 to 6. This selectivity is greater than that obtained from other processes wherein the typical photoresist selectivity is about 1.

As shown in the example result of FIG. 11, the profile of the resulting trenches 1140, have vertical and straight sidewalls 1142. The trenches 1140 also have bottom surfaces 1144 that are flat. The sidewalls 1142 include projections 1146 extending outward. The projections 1146 are depositions of polymer let over from the etch, which are removed when the photoresist is removed to provide more uniform straight sidewalls 1142. The photoresist layer 1130 has a sufficient certain thickness that has been retained after the etch, which acts to prevent the striations, pinholes, or other etching in the photoresist 1130.

Common to Examples 7 and 8 is the structure which is etched. These structures are on a 300 mm diameter wafer with a layering as shown in FIG. 12. The etch structure 1200 includes a barrier layer 1210, an inter-level dielectric (ILD) layer 1220, above the barrier layer 1210, a cap layer 1230 over the ILD layer 1220, an anti-reflective layer or ARC 1240 on the cap layer 1230, and a photoresist layer or PR 1250 on top of the ARC layer 1240. In each of the examples the barrier layer 1210 is an N-BLOK available from Applied Materials of San Jose, Calif., U.S.A., which functions as an etch stop. The dielectric material of the ILD layer 1220 is SiCOH, BLACK DIAMOND I which as noted above, is available from Applied Materials of San Jose, Calif. Cap layer 1230 is a TEOS layer, and the ARC layer 1240 is a standard organic anti-reflective layer. Namely, the ARC is BREWER ARC 29A available from Brewer of Rolla, Mo. The cap layer, which can include SiO2, SiC, and Si3N4 is used to increase mechanical strength to the low k structure to withstand CMP planarization. The photoresist 1250 used is TOK7A7O a 193 nm photoresist, which is available from TOK, Tokyo Ohka Kogyo Co., Ltd. of Kawasaki City, Japan.

### EXAMPLE 7

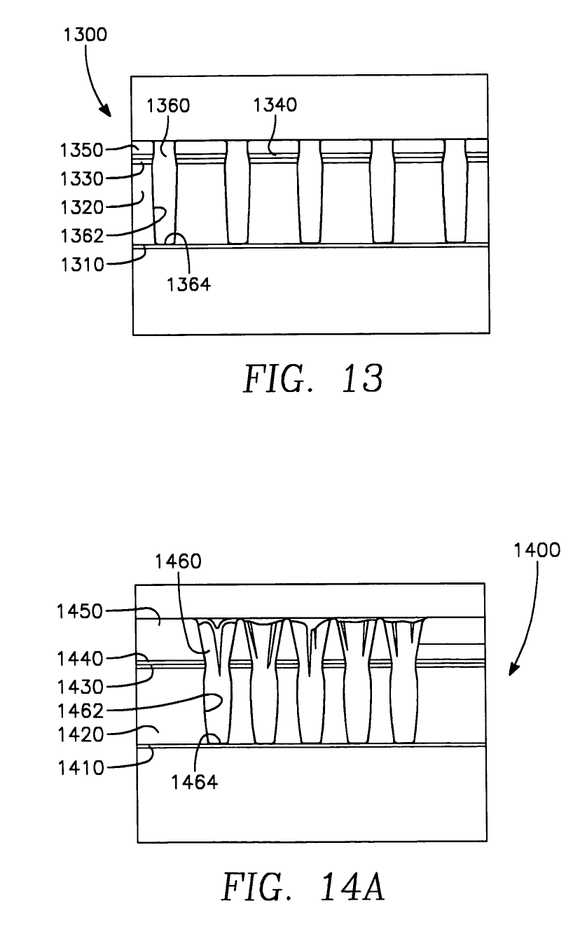

In another example of an embodiment of the present invention, a via is etched in a multiple step etch process with the dielectric being etched by a reduced hydrogen gas mixture. The reduced hydrogen flow is relative to the higher hydrogen flows set forth in other examples herein. An etched vias resulting from this example are shown in the rendering of the cross-section of FIG. 13.

The first step of the etching process of this example is to provide a structure to be etched. As with the prior examples, the etch structure employed in this example is that shown in FIG. 12, with the structure 1200 and various layer and structures as set forth in detail above. Also, as noted the etching is performed in an APPLIED ENABLER ETCH tool with a 300 mm wafer.

The first of these etch steps is an ARC open and TEOS cap open etch where the ARC and cap layers are etched through to allow for later etching of the dielectric layer. During the arc open etch the gas mixture includes 150 sccm of CF₄, 30 sccm of CHF₃ at a pressure of 300 mTorr. The bias is 2000 Watts and the source at 0 Watts. The APPLIED ENABLER ETCH tool has the NSTU set at 1.35, the CSTU inner/outer (i/o) set at 4/0, and the wafer/chuck cooling Helium (He) inner/outer (in-out) pressures are 10T-10T. The etching duration is 30 seconds.

Next, a transition step is performed with 400 sccm of Ar at 20 mTorr, a bias of 200 Watts and a source of 150 Watts. The ENABLER ETCH tool has the NSTU set at 3, the CSTU inner/outer (i/o) set at 4.7/0, and the wafer/chuck cooling Helium (He) inner/outer (in-out) pressures are 20T-10T. The duration of the transition is 5 seconds.

With the BARC and cap opened the main etch is performed to etch the dielectric. In this example the main etch is divided into two portions a first main etch or ME1 and a second main etch or ME2. The gas mixture applied during the ME1 includes gas flows of 50 sccm of H₂, 15 sccm of C₄F₆, 30 sccm of CH₂F₂, 150 sccm of N₂ and 400 sccm of Ar, at a pressure of 15 mTorr. The plasma formed for the etch has the RF bias at 13.56 MHz at 1200 Watts and the source at 150 Watts. The APPLIED ENABLER ETCH tool has the NSTU set at 3, the CSTU inner/outer (i/o) set at 4.7/0, and the wafer/chuck cooling Helium (He) inner/outer (in-out) pressures are 20T-10T. Once the plasma is formed the structure is etched for 35 seconds.

The gas mixture applied during the ME2 includes gas flows of 0 sccm of H₂, 15 sccm of C₄F₆, 10 sccm of CH₂F₂, 200 sccm of N₂ and 400 sccm of Ar, at a pressure of 15 mTorr. The plasma formed for the etch has the RF bias at 13.56 MHz at 3000 Watts and the source at 150 Watts. The APPLIED ENABLER ETCH tool has the NSTU set at 5, the CSTU inner/outer (i/o) set at 4.7/0, and the wafer/chuck cooling Helium (He) inner/outer (in-out) pressures are 20T-10T. Once the plasma is formed the structure is etched for 20 seconds with the etch terminating just prior to reaching the barrier 1210.

Next, to etch to the barrier 1210 an over etch or OE step is used. The over etch step of this example includes flows of 13 sccm of C4F6, 200 sccm of N2, 200 of Ar, at a pressure of 20 mTorr a bias of 3000 Watts, a source of 0 Watts, a NSTU of 9, CSTUo of 2.5/0, He in-out of 15T-15T, for a duration of 40 seconds.

The results of the etch for this example is shown in FIG. 13. As shown, a structure 1300 has been etched to define vias 1360. The structure 1300 includes a barrier layer 1310, an ILD layer 1320 is position above the barrier layer 1310, a cap layer 1330 is over the ILD layer 1320, an ARC layer 1340 is on the cap layer 1330, and a PR layer 1350 is on top of the ARC layer 1340.

In this example, the photoresist selectivity is infinitity for the H₂ containing process. This selectivity is greater than that obtained from other processes wherein the typical photoresist selectivity is about 3 to 5.

As shown, the profile of the resulting vias 1360 with vertical sidewalls 1362. The vias 1360 are shown with a bottom or stop 1364 at, or about the barrier layer 1310, which are flat.

### EXAMPLE 8

An additional example of an embodiment of the present invention includes etching vias in a multiple step etch processes, with the dielectric being etched by a reduced hydrogen gas mixture. In this example, the bias power is a combination of 50% 2 MHz bias and 50% 13.56 MHz bias. The reduced hydrogen flow is relative to the higher hydrogen flows set forth in other examples herein. Etched vias resulting from this example are shown in the rendering of the cross-section of FIG. 14.

The first step of this example is to provide a structure as shown in FIG. 12. As shown, the structure 1200 has various layers and structures as set forth in detail above. Also, as noted the etching is performed in an APPLIED DFB ENABLER ETCH tool with a 300 mm wafer.

The first of these etch steps is an ARC open and TEOS cap open etch where the ARC and cap layers are etched through to allow for later etching of the dielectric layer. During the arc open etch the gas mixture includes 150 sccm of CF₄, 30 sccm of CHF₃ at a pressure of 300 mTorr. The bias is 13.56 MHz at 2000 Watts and the source at 0 Watts. The APPLIED DFB ENABLER ETCH tool has the NSTU set at 1.35, the CSTU inner/outer (i/o) set at 4/0, and the wafer/chuck cooling Helium (He) inner/outer (in-out) pressures are 10T-10T. The etching duration is 30 seconds.

Next, a transition step is performed with 400 sccm of Ar at 20 mTorr, a bias of 13.56 MHz at 200 Watts and a source of 150 Watts. The DFB ENABLER ETCH tool has the NSTU set at 3, the CSTU inner/outer (i/o) set at 4.7/0, and the wafer/chuck cooling Helium (He) inner/outer (in-out) pressures are 20T-10T. The duration of the transition is 5 seconds.

With the ARC and cap opened the main etch is performed to etch the dielectric. In this example the main etch is divided into two portions a first main etch or ME1 and a second main etch or ME2. The gas mixture applied during the ME1 includes gas flows of 50 sccm of H₂, 15 sccm of C₄F₆, 30 sccm of CH₂F₂, 150 sccm of N₂ and 400 sccm of Ar, at a pressure of 15 mTorr. The plasma formed for the etch has the RF bias at 2 MHz of 600 Watts and an RF bias at 13.56 MHz of 600 Watts, and the source is at 150 Watts. The APPLIED DFB ENABLER ETCH tool has the NSTU set at 3, the CSTU inner/outer (i/o) set at 4.7/0, and the wafer/chuck cooling Helium (He) inner/outer (in-out) pressures are 20T-10T. Once the plasma is formed the structure is etched for 30 seconds.

The gas mixture applied during the ME2 includes gas flows of 0 sccm of H₂, 15 sccm of C₄F₆, 20 sccm of CH₂F₂, 200 sccm of N₂ and 200 sccm of Ar, at a pressure of 15 mTorr. The plasma formed for the etch has the RF bias at 2 MHz of 1500 Watts and an RF bias at 13.56 MHz of 1500 Watts, and the source at 150 Watts. The APPLIED DFB ENABLER ETCH tool has the NSTU set at 3, the CSTU inner/outer (i/o) set at 4.7/0, and the wafer/chuck cooling Helium (He) inner/outer (in-out) pressures are 20T-10T. Once the plasma is formed the structure is etched for 15 seconds with the etch terminating just prior to reaching the barrier 1210.

Next, to etch to the barrier 1210 an over etch or OE step is used. The over etch step of this example includes flows of 13 sccm of C₄F₆, 200 sccm of N2, 200 of Ar, at a pressure of 20 mTorr a RF bias at 2 MHz of 1500 Watts and an RF bias at 13.56 MHz of 1500 Watts, and a source of 0 Watts, a NSTU of 9, CSTUo/i of 2.5/0, He in-out of 15T-15T, for a duration of 45 seconds.

The results of the etch for this example is shown in FIG. 13. As shown, a structure 1400 has been etched to define vias 1460. The structure 1400 includes a barrier layer 1410, an ILD layer 1420 is position above the barrier layer 1410, a cap layer 1430 is over the ILD layer 1420, an ARC layer 1440 is on the cap layer 1430, and a PR layer 1450 is on top of the ARC layer 1440.

In this example, the photoresist selectivity is infinitity for the H₂ containing process. This selectivity is greater than that obtained from other processes wherein the typical photoresist selectivity is about 3 to 5.

As shown in the example result of FIG. 14, the profile of the resulting vias 1460 have vertical sidewalls 1462. The vias 1460 are shown with a bottom or stop 1464 at, or about the barrier layer 1410, which are flat.

Additional Hydrogen Containing Gases:

In embodiments of the present invention, the hydrogen additive is replaced with any of a variety of hydrogen containing additives, such as hydrocarbons and hydrogen rich gases. In certain embodiments, the hydrogen containing gases include CH₄, C₂H₄, NH₃, H₂O and/or silane gases.

### EXAMPLE 9

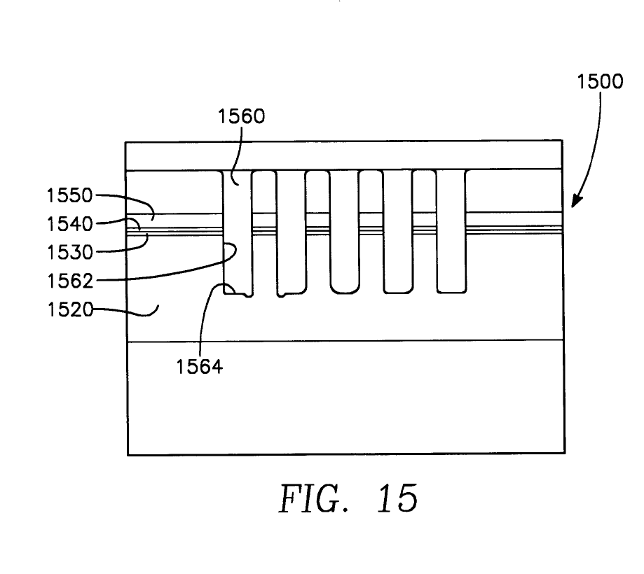

In another example of an embodiment of the present invention, a via is etched in a multiple step etch process with the dielectric being etched by a gas mixture including a hydrocarbon. Etched vias resulting from this example are shown in the rendering of the cross-section of FIG. 15.

This example is similar to that set forth in Example 7, except the first main etch, ME1, instead of using a flow rate of 50 sccm of H₂, CH₄ is used at a flow rate of 25 sccm. Also, the duration of the ME1 is 30 seconds, reduced from 35 seconds of Example 7. Otherwise, the rest of main etch recipe, the etched structure 1200, the BARC etch recipe, and the transition recipe are all the same as in Example 7.

The results of the etch for this example is shown in FIG. 15. As shown, a structure 1500 has been etched to define vias 1560. The structure 1500 includes a barrier layer 1510, an ILD layer 1520 is position above the barrier layer 1510, a cap layer 1530 is over the ILD layer 1520, an ARC layer 1540 is on the cap layer 1530, and a PR layer 1550 is on top of the ARC layer 1540. The profile of the resulting vias 1560 with vertical sidewalls 1562. The vias 1560 are shown with a bottom or stop 1564 at, or about the barrier layer 1510, which are flat.

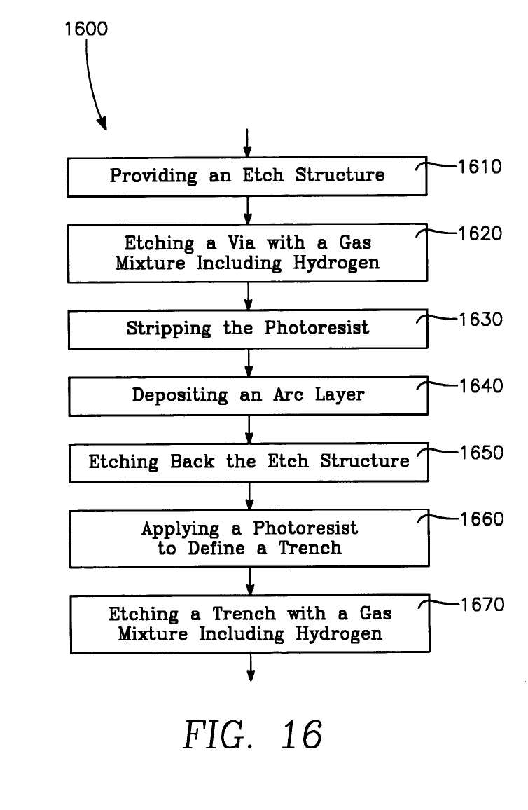

Embodiments of the present invention including etching features to form a dual damascene structure, with at least one embodiment set forth in FIG. 16. As shown, the dual damascene etch method 1600 includes providing an etch structure 1610, etching a via with a gas mixture including hydrogen 1620, stripping the photoresist 1630, depositing an ARC layer 1640, etching back the etch structure 1650, applying a photoresist to define a trench 1660, etching a trench with a gas mixture including hydrogen 1670.

The structure obtained during the step of providing an etch structure 1610 can include any of the structures set forth herein, including in some embodiments a line, a barrier layer over the line, an ILD layer over the barrier, and a patterned photoresist on the ILD, as shown in FIG. 1A. The step etching a via with a gas mixture including hydrogen 1620 can be performed by any of the via etches set forth herein. The gas mixture can include a hydrogen free-fluorocarbon-containing etchant gas, a hydrogen-containing non-etchant gas, a nitrogen-containing gas, and may further include one or more of a hydrofluorocarbon gas, an inert gas, and/or a carbon monoxide gas. One embodiment of a resulting structure is shown in FIG. 1B. Stripping the photoresist 1630 can be done by any of a variety of known methods. The ARC layer of the step of depositing an ARC layer 1640 can depending on the embodiment include any of the ARC materials described herein including DUO, a BARC, and/or a DARC material, which can be applied by any of the herein described methods such as spin-on, CVD or the like. In one embodiment the application of the ARC is shown applied in FIG. 1C. Etching back the etch structure 1650 can be done by any of various known methods, where some of the ARC is left in the via to protect the via during later etching. One embodiment of an etched back structure is shown in FIG. 1D. The step of applying a photoresist to define a trench 1660, also can be done by known methods, with one embodiment of a resulting structure shown in FIG. 1E. Etching a trench with a gas mixture including hydrogen 1670 can be performed by any of the trench etches set forth herein, with a resulting structure shown in one embodiment in FIG. 1B. The gas mixture can include a hydrogen free-fluorocarbon-containing etchant gas, a hydrogen-containing non-etchant gas, a nitrogen-containing gas, and may further include one or more of a hydrofluorocarbon gas, an inert gas, and/or a carbon monoxide gas.

While some embodiments of the present invention have been described in detail above, many changes to these embodiments may be made without departing from the true scope and teachings of the present invention. The present invention, therefore, is limited only as claimed below and the equivalents thereof.

1. An etching method comprising:
a) providing a low-k dielectric material in a chamber;
b) applying into the chamber a gas mixture comprising a first gas comprising a hydrogen-free fluorocarbon, a second gas comprising hydrogen and a third gas comprising nitrogen;
c) forming a plasma with the gas mixture; and
d) etching the low-k dielectric material.

2. The etching method of claim 1, wherein the low-k dielectric material comprises a dielectric material having a dielectric constant less than about 4.0.

3. The etching method of claim 1, wherein the low-k dielectric material comprises a dielectric material having a dielectric constant between about 3.1 and about 2.

4. The etching method of claim 1, wherein the low-k dielectric material comprises a dielectric material having a dielectric constant between about 2.2 and about 2.

5. The etching method of claim 1, wherein low-k dielectric material comprises a carbon-doped silicon oxide.

6. The etching method of claim 1, wherein the first gas is an etchant gas and wherein the second gas is a non-etchant gas.

7. The etching method of claim 6, wherein the gas mixture has a gas ratio of the non-etchant gas to the etchant gas between about 0.6 and about 5.0.

8. The etching method of claim 6, wherein the gas mixture has a gas ratio of the non-etchant gas to the etchant gas between about 1.0 and about 2.5.

9. The etching method of claim 1, wherein the hydrogen-free fluorocarbon of the first gas comprises CₓF_{y}, wherein x≧1 and wherein y≧1.

10. The etching method of claim 1, wherein the hydrogen-free fluorocarbon of the first gas comprises at least one of: (1) CF₄; (2) C₂F₂; (3) C₂F₄; (4) C₃F₆; (5) C₄F₆; (6) C₄F₈; (7) C₅F₈; or (8) C₆F₆.

11. The etching method of claim 1, wherein the second gas comprises at least one of: (1) a diatomic hydrogen; (2) a hydrocarbon; (3) a silane; or (4) a fluorine-free hydrogen gas.

12. The etching method of claim 1, wherein the second gas comprises at least one of: (1) H₂; (2) CH₄; (3) C₂H₄; (4) NH₃; or (5) H₂O.

13. The etching method of claim 1, wherein the second gas comprises H₂.

14. The etching method of claim 1, wherein the third gas comprises N₂.

15. The etching method of claim 1, wherein the gas mixture further comprises a hydrofluorocarbon gas.

16. The etching method of claim 15, wherein the hydrofluorocarbon gas further comprises CₓH_{y}F_{z} wherein x≧1, wherein y≧1, and wherein z≧1.

17. The etching method of claim 15, wherein the hydrofluorocarbon gas comprises at least one of: (1) C₂HF₅; (2) CHF₃; (3) CH₂F₂; (4) CH₃F; (5) C₃H₂F₆; (6) C₃H₂F₄; (7) C₃HF₅; or (8) C₃HF₇.

18. The etching method of claim 1, wherein applying a gas mixture comprises applying a gas mixture at a pressure between about 5 mTorr and about 400 mTorr.

19. The etching method of claim 1, wherein applying a gas mixture further comprises applying a gas mixture at a pressure between about 5 mTorr and about 30 mTorr.

20. The etching method of claim 1, wherein forming a plasma further comprises forming a plasma at at least two bias frequencies.

21. The etching method of claim 1, wherein forming a plasma further comprises forming a plasma at at least one bias frequency of: (1) substantially 2 MHz; or (2) substantially 13.56 MHz.

22. The etching method of claim 1, wherein the gas mixture comprises an oxygen-free gas mixture.

23. The etching method of claim 1, wherein the gas mixture further comprises an inert gas.

24. The etching method of claim 1, wherein the gas mixture further comprises a carbon monoxide gas

25. In a chamber, a plasma etching method for forming a feature, the plasma etching method comprising:
a) providing in the chamber a dielectric material having a dielectric constant less than about 3.7;
b) applying into the chamber a gas mixture comprising a hydrogen-free-fluorocarbon-containing etchant gas, a hydrogen-containing non-etchant gas, a nitrogen-containing gas, and an inert gas;
c) forming a plasma with the gas mixture; and
d) etching the dielectric material to form at least a portion of the feature.

26. The plasma etching method of claim 25, wherein the dielectric constant is between about 3.1 and about 2.

27. The plasma etching method of claim 25, wherein dielectric material comprises a carbon-doped silicon oxide.

28. The plasma etching method of claim 25, wherein the gas mixture has a gas ratio of the non-etchant gas to the etchant gas of between about 0.6 and about 2.7.

29. The plasma etching method of claim 25, wherein the gas mixture further comprises a hydrofluorocarbon-containing etchant gas.

30. The plasma etching method of claim 29, wherein the gas mixture has a gas ratio of the non-etchant gas to the etchant gases of between about 0.55 and about 2.1.

31. The plasma etching method of claim 29, wherein the gas mixture has a gas ratio of the non-etchant gas to the etchant gases of about 1.1.

32. The plasma etching method of claim 25, wherein the hydrogen-free-fluorocarbon-containing etchant gas is at least one of: (1) CF₄; (2) C₂F₂; (3) C₂F₄; (4) C₃F₆; (5) C₄F₆; (6) C₄F₈; (7) C₅F₈; or (8) C₆F₆.

33. The plasma etching method of claim 29, wherein the hydrofluorocarbon-containing etchant gas is at least one of: (1) C₂HF₅; (2) CHF₃; (3) CH₂F₂; (4) CH₃F; (5) C₃H₂F₆; (6) C₃H₂F₄; (7) C₃HF₅; or (8) C₃HF₇.

34. The plasma etching method of claim 25, wherein the hydrogen-containing non-etchant gas is at least one of: (1) H₂; (2) CH₄; (3) C₂H₄; (4) NH₃; or (5) H₂O.

35. The plasma etching method of claim 25, wherein the nitrogen-containing gas is N₂.

36. The plasma etching method of claim 25, wherein the inert gas comprises at least one of: (1) He; (2) Ne; (3) Kr; (4) Xe; or (5) Ar.

37. The plasma etching method of claim 25, wherein applying into the chamber a gas mixture further comprises applying into the chamber a gas mixture at a pressure between about 5 mTorr and about 30 mTorr.

38. The plasma etching method of claim 25, wherein forming a plasma further comprises forming a plasma at at least one bias frequency of: (1) substantially 2 MHz; (2) substantially 13.56 MHz; or (2) substantially 162 MHz.

39. The plasma etching method of claim 25, wherein the gas mixture comprises an oxygen-free gas mixture.

40. The plasma etching method of claim 25, wherein the hydrogen-containing non-etchant gas has flow rate between about 10 sccm and about 250 sccm.

41. The plasma etching method of claim 25, wherein the hydrogen-containing non-etchant gas has a flow rate between about 10 sccm and about 75 sccm.

42. The plasma etching method of claim 25, wherein the hydrogen-free-fluorocarbon-containing etchant gas has a flow rate between about 20 sccm and about 200 sccm.

43. The plasma etching method of claim 29, wherein the hydrofluorocarbon-containing etchant gas has a flow rate between about 20 sccm and about 200 sccm.

44. The plasma etching method of claim 29, wherein the hydrogen-free-fluorocarbon-containing etchant gas and the hydrofluorocarbon-containing etchant gas have a combined flow rate between about 10 sccm and about 200 sccm.

45. The plasma etching method of claim 25, wherein the nitrogen-containing gas has a flow rate between about 0 sccm and about 200 sccm.

46. The plasma etching method of claim 25, wherein the inert gas has a flow rate between about 0 sccm and about 800 sccm.

47. The plasma etching method of claim 25, wherein forming a plasma comprises forming a plasma with a source power between about 0 Watts and about 2000 Watts.

48. The plasma etching method of claim 25, wherein forming a plasma comprises forming a plasma with a source power between about 0 Watts and about 200 Watts.

49. The plasma etching method of claim 25, wherein forming a plasma comprises forming a plasma with a bias power between about 300 Watts and about 3000 Watts.

50. The plasma etching method of claim 25, wherein forming a plasma comprises forming a plasma with a electron density between about 5×10⁹ electrons/cm³ and about 5×10¹¹ electrons/cm³.

51. The plasma etching method of claim 25, wherein forming a plasma comprises forming a plasma with a electron density greater than about 5×10¹⁰ electrons/cm³.

52. A damascene etching method comprising:
a) providing a semiconductor wafer having a low-k dielectric layer and a first patterned photoresist layer over the low-k dielectric layer;
b) applying a first gas mixture comprising a hydrogen-free-fluorocarbon-containing etchant gas, a hydrogen-containing non-etchant gas, a nitrogen-containing gas, and an inert gas;
c) etching the low-k dielectric layer to form a first feature in the semiconductor wafer;
d) stripping the first photoresist layer;
e) depositing an ARC layer on the semiconductor wafer;
f) etching the ARC layer;
g) applying on the semiconductor wafer a second patterned photoresist layer defining a second feature;
h) applying a second gas mixture comprising a hydrogen-free-fluorocarbon-containing etchant gas, a hydrogen-containing non-etchant gas, a nitrogen-containing gas, and an inert gas; and
i) etching the low-k dielectric layer and the ARC layer to form a second feature in the semiconductor wafer.
